(19) United States
(12) Patent Application Publication
(10) Pub. No.: US 2008/0258205 A1
(43) Pub. Date: Oct. 23, 2008

(54) NON-VOLATILE SEMICONDUCTOR MEMORY DEVICE

(75) Inventors: Tetsuya ISHIMARU, Tokyo (JP); Yasuhiro SHIMAMOTO, Tokorozawa (JP); Kan YASUI, Kodaira (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 12/103,697

(22) Filed: Apr. 15, 2008

(30) Foreign Application Priority Data
Apr. 17, 2007 (JP) JP2007-108145

(51) Int. Cl. H01L 29/792

(52) U.S. Cl. 257/324; 257/E29.309

(57) ABSTRACT

An erase current of a non-volatile semiconductor memory device is decreased. A memory cell of the non-volatile semiconductor memory device comprises a source region and a drain region formed in a semiconductor substrate. Over a portion of the semiconductor substrate between the source region and the drain region, a select gate electrode is formed via a gate dielectric film. On a side wall of the select gate electrode, a memory gate electrode is formed via a bottom silicon oxide film and a charge-trapping silicon oxynitride film. In the memory cell configured as above, erase operation is performed as follows. By applying a positive voltage to the memory gate electrode, holes are injected from the memory gate electrode into the silicon oxynitride film to decrease a threshold voltage in a program state to a certain level. Thereafter, hot holes generated by a band-to-band tunneling phenomenon are injected into the silicon oxynitride film and the erase operation is completed.

### CROSS-REFERENCE TO RELATED APPLICATION

The present application claims priority from Japanese Patent Application No. JP 2007-108145 filed on Apr. 17, 2007, the content of which is hereby incorporated by reference into this application.

### TECHNICAL FIELD OF THE INVENTION

The present invention relates to a non-volatile semiconductor memory device, in particular, to the non-volatile semiconductor memory device suitable for decreasing an erase current.

### BACKGROUND OF THE INVENTION

As the non-volatile semiconductor memory device, an EEPROM (Electrically Erasable and Programmable Read Only Memory) and a flash memory are widely used. These non-volatile semiconductor memory devices (memories) comprise charge accumulation films such as conductive floating gate electrodes or a charge-trapping dielectric film under the gate electrode of a MOS (Metal Oxide Semiconductor) transistor and store information using a threshold voltage shift of the transistor varied according to a charge accumulation state of the floating gate electrode or the charge-trapping dielectric film.

The charge-trapping dielectric film refers to a dielectric film having a trap level capable of accumulating the charge, and as an example thereof, there are a silicon nitride film and the like. By injection and discharge of the charges of such a charge-trapping dielectric film, the threshold of the MOS transistor is shifted to operate as a storage element. The non-volatile semiconductor device having such a charge-trapping dielectric film is called a MONOS (Metal Oxide Nitride Oxide Semiconductor)-type transistor, and has excellent reliability of data retention compared with having non-volatile memory having conductive floating gate electrode because the charges are accumulated at the discrete traps. And, due to this excellent reliability of the data retention, a thickness of the silicon oxide film over and under the charge-trapping dielectric film can be reduced, and therefore, the MONOS-type transistor has advantages that voltages in program operation and erase operation can be decreased and the like.

FIG. 34 is a diagram showing a cross-sectional structure of the general MONOS-type transistor. In FIG. 34, a p-type well PWEL is formed in a semiconductor substrate PSUB. In the side of the surface of semiconductor substrate in the p-type well PWEL, a source region MS and a drain region MD are formed with a predetermined distance therebetween. Between the source region MS and the drain region MD, a select gate electrode SG is formed on a gate dielectric film SGOX to form a select transistor. On the other hand, over one side wall of the select gate electrode SG, a memory gate electrode MG is formed on a bottom silicon oxide film BOTOX, a silicon nitride film SIN and a top silicon oxide film TOPOX to form a memory transistor. The MONOS-type transistor shown in FIG. 34 is composed of the select transistor and the memory transistor.

In the MONOS-type transistor mentioned above, the silicon nitride film SIN serves as the charge accumulation film. The program operation is performed by injecting electrons into this silicon nitride film SIN, and the erase operation is performed by discharging electrons from the silicon nitride film SIN or injecting holes into the silicon nitride film SIN. In a program state in which electrons are injected into the silicon nitride film SIN, a threshold voltage of the memory transistor is increased. On the other hand, in a state in which electrons are discharged from the silicon nitride film SIN or holes are injected into the silicon nitride film, the threshold voltage of the memory transistor is decreased. Therefore, in read operation, in the state in which electrons are injected into the silicon nitride film SIN, a current is prevented from being carried between the source region MS and the drain region MD of the memory transistor. On the other hand, in the state where electrons are discharged from the silicon nitride film SIN or holes are injected into the silicon nitride film, the current is carried between the source region MS and the drain region MD of the memory transistor. With this, the information can be stored in the memory transistor.

For example, Japanese Patent Application Laid-Open Publication No. 2005-317965 (Patent Document 1) discloses a technique of performing erase operation by injecting holes into a charge-trapping silicon nitride film utilizing a band-to-band tunneling phenomenon (hereinafter, referred to as BTBT erase). And, there is description about a technique in which, before or after the BTBT erase, a voltage of −20V to −23V is applied to a gate electrode, which leads to the electron injection from the gate electrode into the charge-trapping silicon nitride film via a top silicon oxide film by an FN (Fowler-Nordheim) tunneling phenomenon or electron discharge from the charge-trapping silicon nitride film to a semiconductor substrate via a bottom silicon oxide film. As a result, the deterioration of a data retention characteristic due to the localization of charges, which is a problem in the BTBT erase, is improved.

### SUMMARY OF THE INVENTION

As one of erase methods of the MONOS-type transistor, there is a method of injecting holes into the charge trapping film or discharging electrons from the charge trapping film utilizing a FN tunneling phenomenon or a direct tunneling phenomenon. This erase method utilizing a tunneling phenomenon has an advantage that an erase current is small, and on the other hand, has a problem that the threshold voltage of the memory transistor cannot be sufficiently decreased after erase.

Therefore, as another one of the erase methods of the MONOS-type transistor, there is a method of injecting hot holes generated by the band-to-band tunneling phenomenon into the charge accumulation film. Specifically, by applying a positive voltage to the source region MS and applying a negative voltage to the memory gate electrode MG, holes are generated at an end of the source region MS by the band-to-band tunneling phenomenon. Then, the generated holes are accelerated by an electric field generated by high voltages applied to the source region MS and the memory gate electrode MG to be hot holes, and the generated hot holes are injected into the charge-trapping 5 silicon nitride film SIN, so that the erase operation is performed (see FIG. 34). According to this BTBT erase method, since hot holes are injected into the charge trapping film, the charge trapping film can be made to transit to a positive-charge accumulation state passing through a charge neutral state. Therefore, the threshold voltage of the memory transistor can be sufficiently decreased, a large read current can be obtained, and therefore, this method is suitable for high-speed operation.

However, in the BTBT erase method, there is a problem that the erase current becomes large. Specifically, the erase current carried in the BTBT erase method is larger than that in the erase method of injecting or discharging the charge by the FN tunneling method by approximately nine orders. If the erase current is large, a charge pumping circuit with a large area for supplying a current is required, and as a result, an area of a memory module becomes large. And, if the erase current is large, there are problems that the number of memory cells erased at the same time is restricted and an erase time for the entire erase block becomes long.

An object of the present invention is to provide a technique capable of decreasing the erase current while keeping the advantages of the BTBT erase method.

The above and other objects and novel characteristics of the present invention will be apparent from the description of this specification and the accompanying drawings.

The typical ones of the inventions disclosed in this application will be briefly described as follows.

A non-volatile semiconductor memory device of the present invention is a non-volatile semiconductor memory device comprising: memory cells including (a) a first semiconductor region and a second semiconductor region formed in a semiconductor substrate so as to be separated from each other; (b) a first dielectric film formed over an upper portion of the semiconductor substrate over a portion between the first semiconductor region and the second semiconductor region; and (c) the first gate electrode formed over the first dielectric film, wherein the first dielectric film comprises: (b1) a silicon oxide film; and (b2) the charge accumulation film with a function of accumulating charges formed over the silicon oxide film and contacting a first gate electrode directly, wherein first operation of making a threshold voltage of the memory cell lower than a threshold voltage of the memory cell in a program state is performed by applying a positive voltage larger than a voltage applied to the semiconductor substrate to the first gate electrode, and then, second operation of making the threshold voltage of the memory cell still lower is performed by injecting holes into the charge accumulation film generated using a band-to-band tunneling phenomenon in the semiconductor substrate so as to complete erase operation.

The effects obtained by typical aspects of the present invention will be briefly described below.

By decreasing the erase current of the non-volatile semiconductor memory device, an occupied area of the charge pumping circuit can be decreased and the area of the memory module can be decreased. In other words, by reducing the erase current of the non-volatile semiconductor memory device, the number of cells erased at the same time can be increased and the erase time can be decreased.

### BRIEF DESCRIPTIONS OF THE DRAWINGS

FIG. 1 is a cross-sectional view of main portions of a non-volatile semiconductor memory device (memory cell) according to a first embodiment of the present invention;

FIG. 2 is a diagram showing conditions of voltages applied to respective portions of a selected memory cell at program, erase and read of the non-volatile semiconductor memory device shown in FIG. 1;

FIG. 3 is a diagram showing a movement of charges at the program of the non-volatile semiconductor memory device shown in FIG. 1;

FIG. 4 is a flowchart showing erase operation according to the first embodiment;

FIG. 5 is a diagram showing a movement of charges at FN stress application in the non-volatile semiconductor memory device shown in FIG. 1;

FIG. 6 is a graph showing change of a threshold voltage of the memory cell when a positive voltage is applied to a memory gate electrode (FN stress application) in the non-volatile semiconductor memory device shown in FIG. 1;

FIG. 7 is a diagram showing a movement of charges at BTBT erase in the non-volatile semiconductor memory device shown in FIG. 1;

FIG. 8 is a diagram showing time changes of erase currents at the BTBT erase in a case in which the FN stress application is performed and in a case in which the FN stress application is not performed in the non-volatile semiconductor memory device shown in FIG. 1;

FIG. 9 is a diagram showing time changes of threshold voltages at the BTBT erase in the case in which the FN stress application is performed and in the case in which the FN stress application is not performed in the non-volatile semiconductor memory device shown in FIG. 1;

FIG. 10 is a circuit diagram of a memory array according to the first embodiment;

FIG. 11 is a diagram showing conditions of voltages applied to respective lines at the program, the erase and the read in the memory array;

FIG. 12 is a diagram showing a voltage application sequence in the erase operation;

FIG. 13 is a diagram showing voltage conditions in the case in which application voltages are increased in stages at the BTBT erase after the FN stress application;

FIG. 14 is a circuit diagram showing another memory array according to the first embodiment;

FIG. 15 is a circuit diagram showing another memory array according to the first embodiment;

FIG. 16 is a cross-sectional view of main portions showing a manufacturing process of the non-volatile semiconductor memory device according to the first embodiment;

FIG. 17 is a cross-sectional view of the main portions showing the manufacturing process of the non-volatile semiconductor memory device continued from FIG. 16;

FIG. 18 is a cross-sectional view of the main portions showing the manufacturing process of the non-volatile semiconductor memory device continued from FIG. 17;

FIG. 19 is a cross-sectional view of the main portions showing the manufacturing process of the non-volatile semiconductor memory device continued from FIG. 18;

FIG. 20 is a cross-sectional view of the main portions showing the manufacturing process of the non-volatile semiconductor memory device continued from FIG. 19;

FIG. 21 is a cross-sectional view of the main portions showing the manufacturing process of the non-volatile semiconductor memory device continued from FIG. 20;

FIG. 22 is a cross-sectional view of the main portions showing the manufacturing process of the non-volatile semiconductor memory device continued from FIG. 21;

FIG. 23 is a cross-sectional view of the main portions showing the manufacturing process of the non-volatile semiconductor memory device continued from FIG. 22;

FIG. 24 is a cross-sectional view of main portions of the another non-volatile semiconductor memory device according to the first embodiment;

FIG. 25 is a cross-sectional view of main portions of another non-volatile semiconductor memory device according to the first embodiment;

FIG. 26 is a cross-sectional view of main portions of another non-volatile semiconductor memory device according to the first embodiment;

FIG. 27 is a cross-sectional view of main portions of a non-volatile semiconductor memory device according to a second embodiment of the present invention;

FIG. 28 is a diagram showing conditions of voltages applied to respective portions of a selected memory cell at program, erase and read of the non-volatile semiconductor memory device according to the second embodiment of the present invention;

FIG. 29 is a diagram showing a movement of charges at the program of the non-volatile semiconductor memory device shown in FIG. 27;

FIG. 30 is a diagram showing a movement of charges at FN stress application in the non-volatile semiconductor memory device shown in FIG. 27;

FIG. 31 is a diagram showing a movement of charges at BTBT erase in the non-volatile semiconductor memory device shown in FIG. 27;

FIG. 32 is a circuit diagram of a memory array according to the second embodiment;

FIG. 33 is a diagram showing conditions of voltages applied to respective lines at the program, the erase and the read in the memory array; and

FIG. 34 is a cross-sectional view of main portions of a memory cell showing BTBT erase operation in a non-volatile semiconductor memory device studied by the inventors.

### DESCRIPTIONS OF THE PREFERRED EMBODIMENTS

In the following embodiments, a description will be given by dividing into a plurality of sections or embodiments as occasion demands as a matter of convenience. However, except the case of a particularly clear description, the elements are not independent with each other, but one is a modified example, details, a supplementary explanation or the like of a part or a whole of the other.

Further, in the following embodiments, in the case of referring to a number of elements (including a number, a numerical value, an amount, a range and the like), the present invention is not limited to the defined number except the case of the particular definition and the case of apparently limited to the specific number in principle, but may be equal to the defined number, more than the defined number, or less than the defined number.

And, in the following embodiments, components (including elemental steps and the like) thereof are not necessarily indispensable except the case of the particular definition and the case of apparent in principle.

And, in the following embodiments, in the case of referring to a shape, a positional relation and the like, ones substantially the same or similar thereto are included except the case of the particular definition and the case of not included apparently in principle.

And, the components are denoted by the same reference symbols throughout the drawings for describing the embodiment, and the repetitive description thereof will be omitted. Note that, hatching may be made even in a plane diagram for ease of understanding.

In the following embodiments, explanation is made to an n-channel-type memory cell. A p-channel-type memory cell can be dealt in the same way.

### First Embodiment

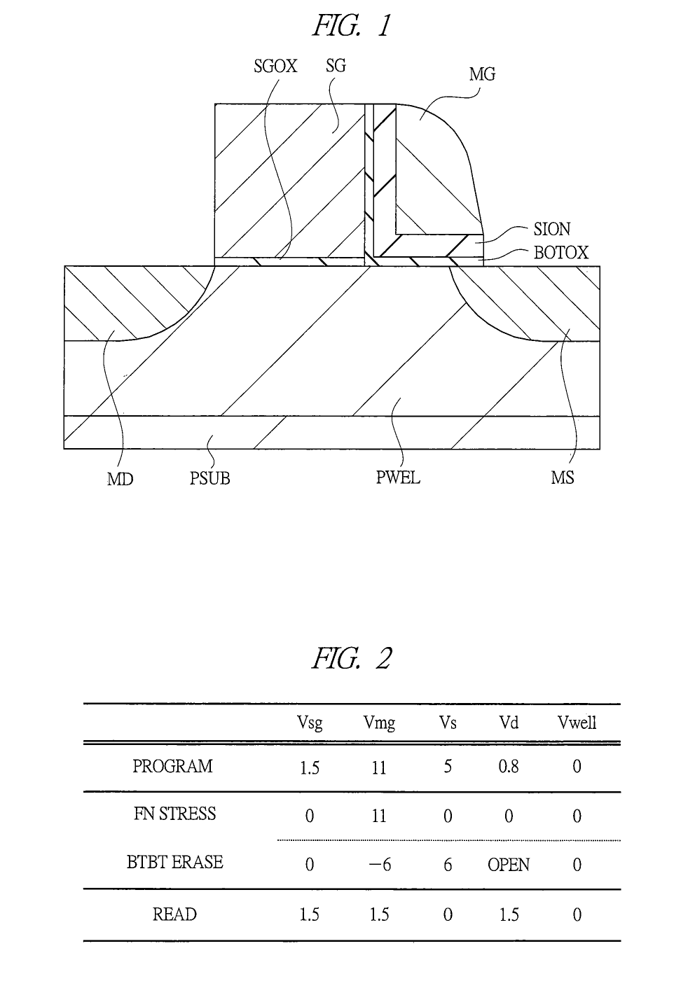

FIG. 1 is a cross-sectional view of main portions of a memory cell configuring a representative non-volatile semiconductor memory device (flash memory) according to a first embodiment. The memory cell shown here is a split-gate-type cell using a charge-trapping dielectric film. The charge-trapping dielectric film is a dielectric film having a discrete trap level therein and having a function of accumulating a charge at this trap level.

In the side of the surfaces of semiconductor substrate in the p-type well PWEL, a source region MS and a drain region MD are formed. Between the source region MS and the drain region MD, a select gate electrode SG is formed on a gate dielectric film SGOX to form a select transistor. On the other hand, over one side wall of the select gate electrode SG, a memory gate electrode MG is formed on a bottom silicon oxide film BOTOX, a silicon nitride film SIN and a top silicon oxide film TOPOX to form a memory transistor. The MONOS-type transistor shown in FIG. 34 is composed of the select transistor and the memory transistor.

As shown in FIG. 1, the p-type well PWEL is formed over the semiconductor substrate PSUB. In the side of the surface of semiconductor substrate in the p-type well PWEL, a source region (a source diffusion layer, an n-type semiconductor region) MS and a drain region (a drain diffusion layer, an n-type semiconductor region) are formed with a predetermined distance therebetween. Between the source region MS and the drain region MD, a select gate electrode (a second gate electrode) SG is formed on a gate dielectric film (a second dielectric film) SGOX to form a select transistor. On the other hand, over one side wall of the select gate electrode SG, a memory gate electrode (a first gate electrode) MG is formed on a bottom silicon oxide film BOTOX and a silicon oxynitride film SION to form a memory transistor. A memory cell (MONOS transistor) shown in FIG. 1 is composed of the select transistor and the memory transistor. The select transistor is a MOS transistor composed of the gate dielectric film SGOX, the select gate electrode SG formed on the gate dielectric film SGOX, the source region MS and the drain region MD. The memory transistor is a MOS transistor composed of the silicon oxynitride film SION formed on the bottom silicon oxide film, the memory gate electrode MG directly contacting with the silicon oxynitride film SION, the source region MS and the drain region MD. Here, a first dielectric film is defined as a multilayered film of the bottom silicon oxide film BOTOX and the silicon oxynitride film SION.

The semiconductor substrate PSUB is composed of a silicon substrate having a p-type impurity introduced. The p-type well PWEL is composed of a semiconductor region having the p-type impurity introduced. The source region MS and the drain region MD are composed of semiconductor regions having an n-type impurity introduced. The select gate electrode SG is composed of, for example, an n-type polysilicon film (conductor). Similarly, the memory gate electrode MG is composed of, for example, the n-type polysilicon film (conductor). In the memory cell according to the first embodiment, as the charge accumulation film of the memory transistor, the silicon oxynitride film SION which is one of charge-trapping dielectric films is used.

The memory cell according to the first embodiment is configured as described above, and characteristic configuration thereof is described next. One of features of the first embodiment is that the silicon oxynitride film SION which is one of the charge-trapping dielectric films is used as the charge accumulation film and the memory gate electrode MG is formed so as to directly contact with this silicon oxynitride film SION. That is, one feature is that the top silicon oxide film is not formed between the silicon oxynitride film SION and the memory gate electrode MG.

In a conventional memory cell, as shown in FIG. 34, the silicon nitride film SIN which is the charge accumulation film and the top silicon oxide film TOPOX and the bottom silicon oxide film BOTOX positioned above and below the silicon nitride film SIN respectively are used as gate dielectric films of the memory transistor. On the other hand, in the first embodiment, as shown in FIG. 1, the silicon oxynitride film SION is used as the charge accumulation film, and the top silicon oxide film TOPOX does not exist between the silicon oxynitride film SION and the memory gate electrode MG.

Advantages obtained by the above-described configuration are as follows. That is, as described further below, a feature of the first embodiment is that, first operation injecting holes from the memory gate electrode MG into the silicon oxynitride film utilizing the FN tunneling phenomenon and second operation injecting holes (hot holes) generated by the band-to-band tunneling phenomenon at an end of the source region MS in the semiconductor substrate PSUB into the silicon oxynitride film SION via the bottom silicon oxide film BOTOX after the first operation are performed as erase operation of the memory cell. Therefore, in the first operation described above, the holes are injected from the memory gate electrode MG into the silicon oxynitride film SION. At this time, the top silicon oxide film TOPOX to be a barrier is not formed between the silicon oxynitride film SION and the memory gate electrode MG and configuration is made so that the silicon oxynitride film SION and the memory gate electrode MG directly contact with each other. Thereby, a significant effect that an amount of hole injection from the memory gate electrode MG into the silicon oxynitride film SION can be increased is obtained. By increasing the amount of the hole injection, a threshold voltage of the memory cell can be efficiently decreased. Furthermore, the silicon oxynitride film SION is used as the charge accumulation film and the silicon oxynitride film SION has an advantage of high retention capability of charges. Since the silicon oxynitride film has the advantage, an excellent data retention characteristic can be achieved even if the top silicon oxide film TOPOX is not formed. That is, by using the silicon oxynitride film SION as the charge accumulation film, which is excellent in the data retention characteristic, the top silicon oxide film TOPOX is unnecessary. Therefore, the top silicon oxide film TOPOX is not formed and the silicon oxynitride film SION and the memory gate electrode MG can contact directly with each other, thereby the amount of the hole injection from the memory gate electrode MG into the silicon oxynitride film SION can be increased.

Here, in the memory cell disclosed in Patent Document 1, as the gate dielectric film, an ONO film composed of a multilayered film of a silicon nitride film as the charge accumulation film and silicon oxide films positioned above and below thereof is used. On the other hand, the first embodiment is different in that the silicon oxynitride film SION is used as the charge accumulation film and the silicon oxynitride film SION and the memory gate electrode MG directly contact with each other. Furthermore, in Patent Document 1, a thickness of the silicon oxide film positioned above the silicon nitride film is 3 nm to 10 nm. The hole cannot be injected from the memory gate electrode by the FN tunneling phenomenon in such a thick silicon oxide film.

Primarily, in Patent Document 1, by applying a high voltage of −20V to −23V to the memory gate electrode, electrons are injected from the memory gate electrode into the charge accumulation film by the FN tunneling phenomenon or electrons are discharged from the charge accumulation film to the semiconductor substrate. An object of the invention disclosed in Patent Document 1 is that, by performing the above described operation before and after an erase method of injecting the hot holes generated by the band-to-band tunneling phenomenon into the charge accumulation film (hereinafter referred to as a BTBT erase method), to suppress deterioration of the data retention characteristic due to localization of charges occurring in the BTBT erase method. That is, in Patent Document 1, injection and discharge of electrons are used.

On the other hand, an object of the present invention is to inject holes from the memory gate electrode MG into the silicon oxynitride film SION by the FN tunneling phenomenon as first operation of the erase operation since the erase current is large in the BTBT erase method. By performing this first operation to decrease electrons accumulated in the silicon oxynitride film SION, the erase current in BTBT erase (second operation) performed after the first operation can be decreased.

As described above, the first embodiment is different from Patent Document 1 in that the object thereof is to decrease the erase current by the BTBT erase method. Furthermore, another different point in the first embodiment is that injection of holes from the memory gate electrode MG into the silicon oxynitride film SION in the first operation is utilized. And, in the first embodiment, by configuration in which the silicon oxynitride film SION and the memory gate electrode MG directly contact with each other in addition to using the holes, a voltage applied to the memory gate electrode MG in the first operation can be approximately 10V to 12V. That is, in comparison with a technique disclosed in Patent Document 1, there is an advantage that the first operation can be performed with a lower voltage. As described above, the first embodiment and the technique disclosed in Patent Document 1 are different in objects, configurations and effects.

Note that, an amount of charges that the silicon oxynitride film SION can accumulate is smaller than that of the silicon nitride film. Therefore, to ensure a sufficient amount of charge accumulation, a configuration in which the silicon nitride film is multilayered in the silicon oxynitride film SION or between the silicon oxynitride film SION and the bottom silicon oxide film BOTOX can be employed. That is, as the charge accumulation film, a multilayered film of the silicon nitride film and the silicon oxynitride film SION may be used or the charge accumulation film may be configured of a first silicon oxynitride film, a silicon nitride film formed on this first silicon oxynitride film and a second silicon oxynitride film formed on this silicon nitride film. And, although hole injection efficiency is decreased, in order to obtain more excellent data retention capability, the top silicon oxide film may be provided. In this case, a thickness of the top silicon oxide film is 3 nm or smaller at which the tunneling phenomenon of holes from the memory gate electrode MG occurs. In this case, only the silicon nitride film is used as the charge accumulation film without using the silicon oxynitride film. Although the top silicon oxide film is preferably not formed, if the thickness thereof is 3 nm or smaller, the FN tunneling phenomenon of the holes can occur and there is no problem. As described above, even if the configuration having the top silicon oxide film is employed, the present embodiment is different from the technique disclosed in Patent Document 1 in a film thickness and in that holes are used as a charge to be injected. Even in a case where the top silicon oxide film having the film thickness of 3 nm or smaller, the FN tunneling phenomenon of the hole occurs. Therefore, the voltage applied to the memory gate electrode MG is approximately 10V to 12V and the voltage can be decreased significantly in comparison with that (−20V to −23V) of the technique disclosed in Patent Document 1. Furthermore, by interposing a nano-conductive particle, the silicon nitride film or an amorphous thin film between silicon oxide films, an effective tunnel barrier can be decreased. Accordingly, when the top silicon oxide film is provided, a configuration in which a conductor composed of the silicon nitride film, the nano-conductive particle or the amorphous thin film is interposed in the top silicon oxide film can be employed in order to effectively inject holes from the memory gate electrode MG into the charge accumulation film by the FN tunneling phenomenon.

And, by using a p-type polysilicon film in the memory gate electrode MG instead of the n-type polysilicon film, when holes are injected from the memory gate electrode MG into the charge accumulation film by the FN tunneling phenomenon (first operation), the amount of the hole injection can be increased. In the same way, by decreasing n-type impurity density of the n-type polysilicon film, the amount of the hole injection can be increased also.

Next, program operation, erase operation and read operation of the memory cell according to the first embodiment are explained. FIG. 2 is a diagram showing conditions of voltage application to respective portions of the memory cell at “program”, “erase” and “read”. Here, injection of electrons into the charge-trapping silicon oxynitride film SION is defined to as “program” and injection of holes into the silicon oxynitride film SION is defined as “erase”.

The program operation is performed by hot-electron program so-called a source side injection method. As program voltages, for example, a voltage Vs applied to the source region MS is set to 5V, a voltage Vmg applied to the memory gate electrode MG is set to 11V and a voltage Vsg applied to the select gate electrode SG is set to 1.5V. And, a voltage Vd applied to the drain region MD is controlled so that a channel current at the program becomes a certain set value. The voltage Vd at this time is determined by the set value of the channel current and the threshold voltage of the select transistor. For example, when the set value of the current is 1 μA, the voltage Vd is approximately 0.8V. A voltage Vwell applied to the p-type well PWEL is 0V.

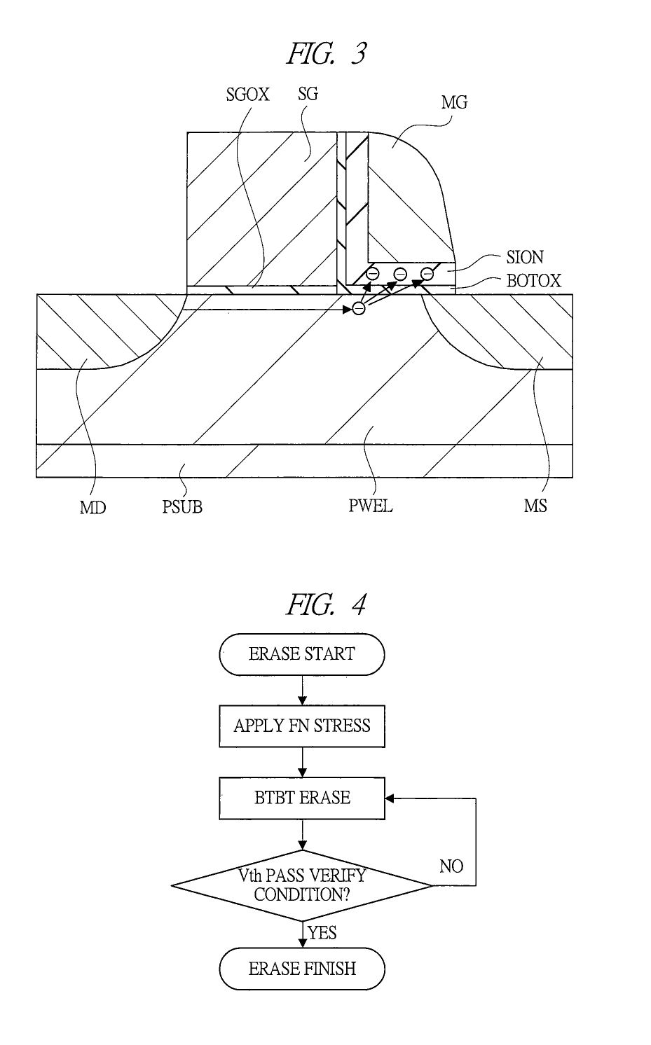

A movement of charges at the program is shown in FIG. 3. As shown in FIG. 3, electrons flow through a channel region formed between the source region MS and the drain region MD. The electron flowing through the channel region is accelerated in the channel region (between the source region MS and the drain region MD) under a portion in a vicinity of a boundary between the select gate electrode SG and the memory gate electrode MG to be the hot electrons. And, the hot electron is injected into the silicon oxynitride film SION under the memory gate electrode MG by an electric field in a vertical direction caused by a positive voltage (Vmg=11V) applied to the memory gate electrode MG. The injected hot electrons are captured at the trap level in the silicon oxynitride film SION, and as a result, the electrons are accumulated in the silicon oxynitride film SION and the threshold voltage of the memory transistor is increased.

Next, the erase operation which is one of features of the first embodiment is described. FIG. 4 is a flowchart showing the erase operation of the memory cell according to the first embodiment. As shown in FIG. 4, after FN stress application is performed first, the BTBT erase is repeated until the threshold voltage reaches a set threshold voltage, thereby the erase operation is performed. Here, the erase operation is assumed to be composed of first operation and second operation. The first operation is operation of injecting holes from the memory gate electrode MG into the charge-trapping silicon oxynitride film SION by the FN tunneling phenomenon. In following description, this first operation is referred to as the FN stress application. On the other hand, the second operation is operation of injecting holes (hot holes) generated by the band-to-band tunneling phenomenon into the charge-trapping silicon oxynitride film SION in a vicinity of a boundary between the p-type well PWEL and the source region MS. In the following description, this second operation is referred to as the BTBT erase.

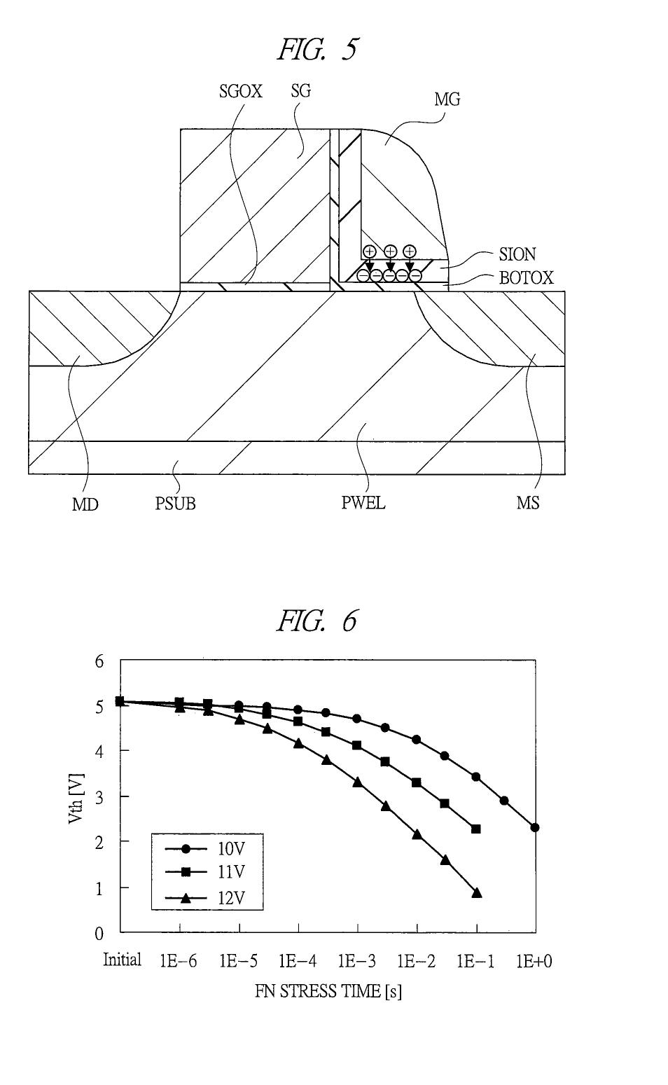

FIG. 5 is a diagram showing a movement of the charges at the FN stress application (first operation). In the FN stress application, as application voltages, for example, the voltage applied to the memory gate electrode MG is set to 11V, and voltages applied to other portions (the voltage Vs applied to the source region MS, the voltage Vsg applied to the select gate electrode SG, the voltage Vd applied to the drain region MD and the voltage Vwell applied to the p-type well PWEL) are set to 0V. By this FN stress application, as shown in FIG. 5, holes are injected from the memory gate electrode MG to decrease the electrons accumulated in the silicon oxynitride film SION in the program operation, and as a result, the threshold voltage of the memory cell (memory transistor) is decreased.

Since voltages of the Vmg applied to the memory gate electrode MG at the FN stress application and at the program are approximately equal to each other (11V), a voltage source applying a voltage to the memory gate electrode MG at the program can also be used at the FN stress application and no voltage source for the FN stress application is newly required. That is, since the voltage source applying the voltage to the memory gate electrode MG can be used for the program and the FN stress application commonly, a configuration of a voltage source circuit is not required to be complex. Therefore, the configuration of the voltage source circuit is simplified and an occupied area of the voltage source circuit can be decreased.

And, the voltage Vd applied to the drain region MD can also be in a floating state in the same manner as in the BTBT erase (second operation). By doing so, voltage switching at transition to the BTBT erase after the FN stress application becomes unnecessary. Furthermore, the voltage Vsg applied to the select gate electrode SG at the FN stress application may be 1.5V instead of 0V. By doing so, voltage applied between the memory gate electrode MG and the select gate electrode SG is decreased and the securement of reliability of the dielectric film formed between the memory gate electrode MG and the select gate electrode SG becomes easy.

FIG. 6 shows change of the threshold voltage of the memory cell (memory transistor) by the FN stress application. In this memory cell, the bottom silicon oxide film BOTOX has a film thickness of 4 nm, the silicon oxynitride film SION as the charge accumulation film has a film thickness of 19 nm and no top silicon oxide film is formed. As is understood from FIG. 6, to decrease the threshold voltage from 5V to 3V by approximately 2V by the FN stress application, it takes approximately 300 ms if the voltage Vmg applied to the memory gate electrode MG is 10V. It takes approximately 30 ms if the voltage Vmg applied to the memory gate electrode MG is 11V and it takes approximately 3 ms when the voltage Vmg applied to the memory gate electrode MG is 12V. From this, it can be understood that, as the voltage Vmg applied to the memory gate electrode MG is increased, an amount of the hole injection into the silicon oxynitride film SION as the charge accumulation film is increased and a time required for decreasing the threshold voltage to the certain threshold voltage is shortened.

And, to decrease the threshold voltage from 5V to 3V by approximately 2V by the FN stress application, it takes approximately 100 ms when the voltage Vmg applied to the memory gate electrode MG is 11V. It takes approximately 10 ms when the voltage Vmg applied to the memory gate electrode MG is 12V. A current flowing during the FN stress application is as small as 10⁻¹⁵ A per memory cell and this FN stress application operation can be performed to all memory cells collectively. When capacity of the non-volatile semiconductor memory device is 512 kB, all memory cells in an erase block thereof are made to be able to be subjected to the FN stress application collectively. Since it takes three or more seconds for all-erase operation in general, increase of erase time due to the FN stress application is not so large. In this manner, as a first step of the erase operation, the electron accumulated in the silicon oxynitride film SION can be decreased by the FN stress application and the threshold voltage of the memory cell (memory transistor) can be decreased to a constant level.

After the first operation by the FN stress application is performed, the second operation by the BTBT erase is performed. Next, the BTBT erase is described.

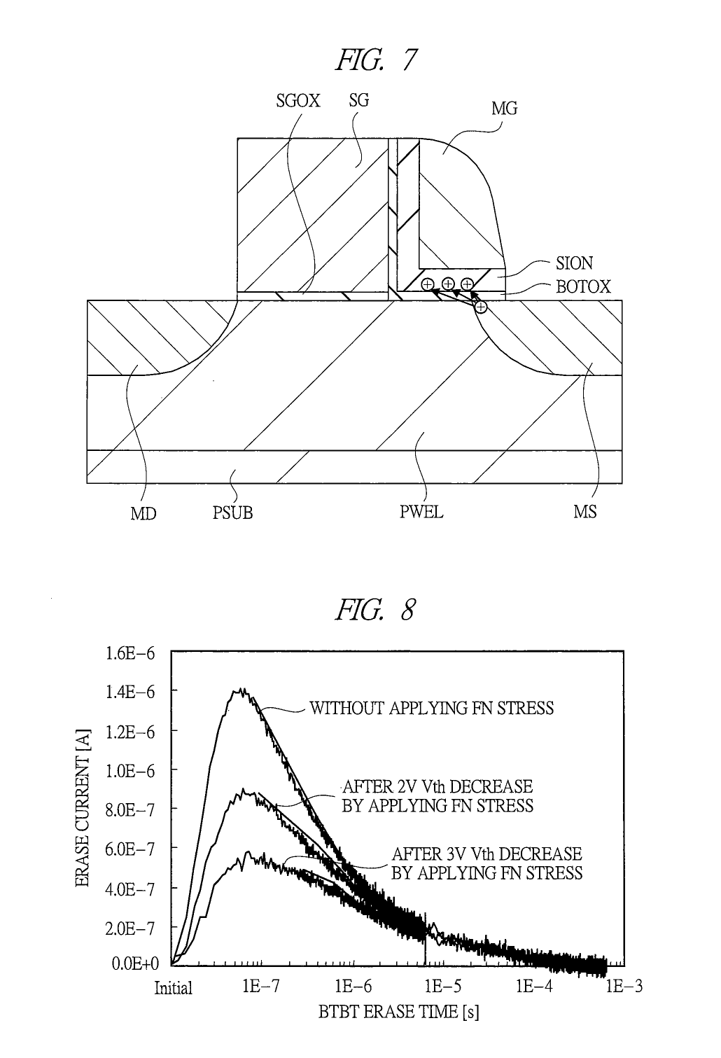

FIG. 7 is a diagram showing a movement of the charges at the BTBT erase after the FN stress application. In the BTBT erase, for example, the voltage Vmg applied to the memory gate electrode MG is set to −6V, the voltage Vs applied to the source region MS is set to 6V and the voltage Vsg applied to the select gate electrode SG is set to 0V. The drain region MD is opened or is applied with 1.5V. By doing so, by the voltage applied between the source region MS and the memory gate electrode MG, holes generated by the band-to-band tunneling phenomenon at the end of the source region MS are accelerated by a high voltage applied to the source region MS to be hot holes. And, a part of the hot holes are drawn to a negative voltage applied to the memory gate electrode MG and are injected into the silicon oxynitride film SION. The injected hot holes are captured at the trap level in the silicon oxynitride film SION and the threshold voltage of the memory cell (memory transistor) is decreased. In the BTBT erase, since hot holes are injected, the charge accumulation film can be a positive charge accumulation state passing through a charge neutral state. Therefore, the threshold voltage of the memory transistor can be sufficiently decreased, the large read current can be obtained, and therefore, this is suitable for high-speed operation.

At the BTBT erase, hot holes injected into the charge-trapping silicon oxynitride film SION are only a part of pairs of electrons and holes generated by the band-to-band tunneling phenomenon and most of the holes are carried to the semiconductor substrate PSUB and most of the electrons are carried to the source region MS. This is the erase current in the BTBT erase, and a current as much as 1 μA per memory cell flows. To supply such a large erase current, the large charge pumping circuit is required. And, if the erase current is large, the number of memory cells can be erased at one time is restricted. For example, even if the charge pumping circuit having supply capability of 1 mA or more is provided, the BTBT erase can be performed only by 1 kbit. As described above, in the BTBT erase, the erase current is increased significantly. Therefore, in the first embodiment, the BTBT erase is not separately performed as the erase operation, but the BTBT erase is performed after the FN stress application. This is one of the features of the first embodiment. That is, by performing the FN stress application before the BTBT erase, the erase current at the BTBT erase can be decreased.

FIG. 8 is a diagram showing that the erase current at the BTBT erase is decreased by the FN stress application. FIG. 8 shows changes of the erase current with time during the BTBT erase in a case where the FN stress is applied and the threshold voltage is decreased by 2V or 3V beforehand and a case where the FN stress is not applied. As is understood from results thereof, the erase current in the BTBT erase is decreased by 40% by decreasing the threshold voltage by 2V by the FN stress application, and is decreased by 60% by decreasing the threshold voltage by 3V by the FN stress application.

Next, a mechanism of decreasing the erase current in the BTBT erase by performing the BTBT erase after the FN stress application is shown. Magnitude of the erase current in the BTBT erase is determined by amounts of electrons and holes generated by the band-to-band tunneling phenomenon. An amount of pairs of the electrons and the holes generated by the band-to-band tunneling phenomenon increases as the electric field in the vertical direction at a position where the band-to-band tunneling phenomenon occurs becomes larger. The electric field in the vertical direction becomes larger as an amount of the electron accumulated in the silicon oxynitride film SION located at an upper portion of the position where band-to-band tunneling phenomenon occurs becomes larger. Therefore, the erase current becomes smaller as the threshold voltage is decreased from a value of a program state. Accordingly, by decreasing the threshold voltage by the FN stress application, the erase current can be decreased. That is, at start of the erase operation, a large amount of electrons is accumulated in the charge-trapping silicon oxynitride film SION. Therefore, the electric field in the vertical direction is increased by the large amount of the electrons accumulated in the silicon oxynitride film SION. If the electric field in the vertical direction is increased, the pair of the electrons and the holes generated by the band-to-band tunneling phenomenon increases, and the erase current becomes larger. Therefore, in the first embodiment, at an initial stage of the erase, holes are injected from the memory gate electrode MG into the silicon oxynitride film SION using the FN tunneling phenomenon which is unrelated to the band-to-band tunneling phenomenon. Thereby, the amount of the electrons accumulated in the silicon oxynitride film SION is decreased. Accordingly, by decreasing the amount of the electrons accumulated in the silicon oxynitride film SION, the electric field in the vertical direction is relaxed. At this stage, the BTBT erase is performed. In the BTBT erase, although the pairs of the electrons and the holes are generated by the band-to-band tunneling phenomenon, since the electric field in the vertical direction is relaxed by the FN stress application, the amount of the pairs of the electrons and the holes to be generated is small. For this reason, the erase current in the BTBT erase can be decreased. Note that, the erase current caused by the FN stress application is extremely small compared with the erase current in the BTBT erase, and therefore, it does not matter. Rather, in the BTBT erase in which the erase current is large, the erase current can be significantly decreased, and therefore, according to the first embodiment, by performing the erase operation by the FN stress application and the BTBT erase, the erase current can be decreased.

The charge pumping circuit can be reduced as much as decrease of the erase current in this manner, and therefore, an area of the memory module can be reduced. In other words, the number of memory cells to be erased at one time is increased as much as decrease of the erase current, and therefore, the total erase time can be reduced.

Here, in contrast to the BTBT erase, according to the FN stress application, the erase current is small, and therefore, it may be considered that the erase operation of the memory cell can be performed only by the FN stress application. However, in the FN stress application, it is difficult to decrease the threshold voltage of the memory cell (memory transistor) to a certain value or less. That is, when a certain amount of the holes is accumulated in the silicon oxynitride film SION, electrons are injected from a semiconductor substrate PSUB (silicon substrate) side and the threshold voltage is saturated. On the other hand, in the BTBT erase, since holes are injected under a condition in which injection of electrons is difficult to occur, the state of the charge accumulation film can be made to transit to the positive-charge accumulation state passing through the charge neutral state. Thereby, the threshold voltage of the memory transistor can be sufficiently decreased, the large read current can be obtained, and therefore, an advantage suitable for the high-speed operation can be obtained. However, in the BTBT erase, there is a problem that the erase current is large. Therefore, in the first embodiment, as the erase operation of the memory cell, the BTBT erase is performed after the FN stress application is performed. With this, a significant effect that the erase current is decreased can be achieved while keeping the advantage of the BTBT erase.

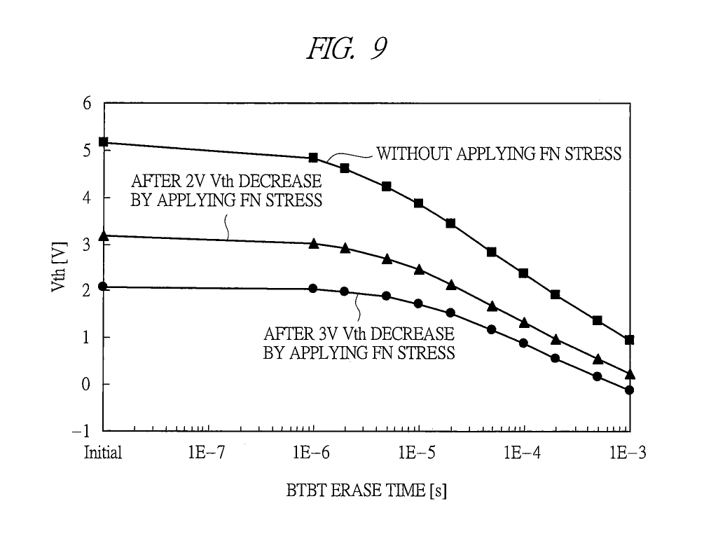

FIG. 9 is a diagram showing erase characteristics of the BTBT erase in a case where the threshold voltage is decreased by the FN stress application and in a case where the threshold voltage is not decreased. As shown in FIG. 9, it can be understood that, by decreasing the threshold voltage by the FN stress application, a time of the BTBT erase required for decreasing the threshold voltage to a certain level is also reduced. As described above, according to the first embodiment, in addition to an effect that the entire erase time is reduced, an effect that deterioration in the bottom silicon oxide film BOTOX caused by the BTBT erase is suppressed can be achieved.

Next, the read operation is described.

As shown in FIG. 2, the read operation is performed by setting the voltage Vd applied to the drain region MD to 1.5V, setting the voltage Vs applied to the source region MS to 0V, setting the voltage Vsg applied to the select gate electrode SG to 1.5V, setting the voltage Vmg applied to the memory gate electrode MG to 1.5V and carrying a current in a direction reverse to the direction in the program. The voltage Vd applied to the drain region MD and the voltage Vs applied to the source region MS may be interchanged to be 0V and 1.5V, respectively, to perform the read operation in which the direction of the current is the same as that in the program. At this time, if the memory cell is in the program state and the threshold voltage is high, no current flows through the memory cell. On the other hand, if the memory cell is in the erase state and the threshold voltage is low, the current flows through the memory cell.

As described above, determination whether the memory cell is in the program state or in the erase state can be made by detecting presence or absence of the current flowing through the memory cell.

In the read operation, the voltage Vmg applied to the memory gate electrode MG is set to a value between the threshold voltage of the memory cell (memory transistor) in the program state and the threshold voltage of the memory cell (memory transistor) in the erase state. For example, if the threshold voltage in the program state is set to 4V and the threshold voltage in the erase state is set to −1V, the voltage Vmg applied to the memory gate electrode MG at reading is set to an intermediate value (2.5V) therebetween. By setting the voltage Vmg applied to the memory gate electrode MG at the read to the intermediate value therebetween, the determination whether the memory cell is in the program state or the erase state can be made even when the threshold voltage in the program state is decreased by 2V or the threshold voltage in the erase state is increased by 2V during data retention, and therefore, a margin of the data retention characteristic is widened. If the threshold voltage of the memory cell (memory transistor) in the erase state is made sufficiently low, the voltage Vmg applied to the memory gate electrode MG at the reading can also be set to 0V. By setting the voltage Vmg applied to the memory gate electrode MG at the reading to 0V, read disturbance, that is, fluctuation of the threshold voltage caused by voltage application to the memory gate electrode MG can be suppressed.

Next, memory operation in a case where an array is composed of a plurality of memory cell is explained.

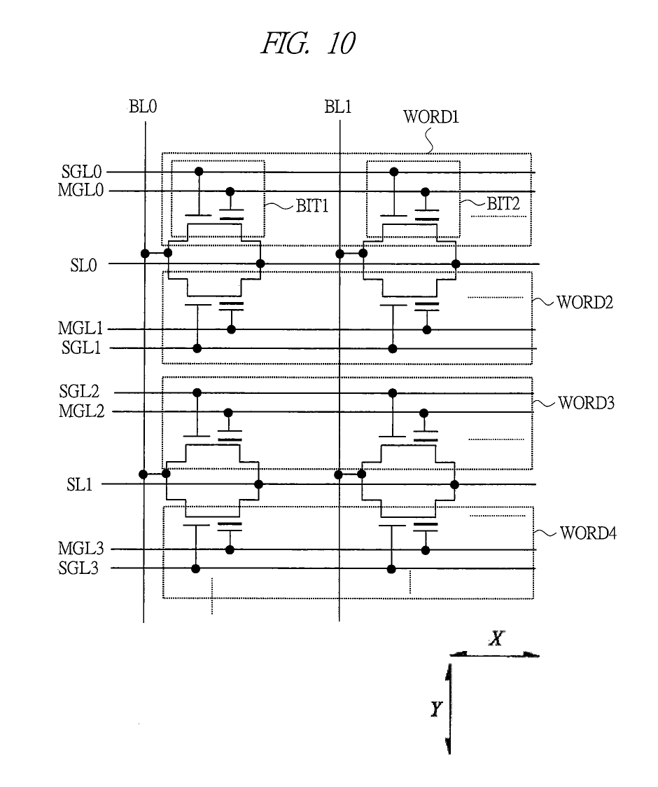

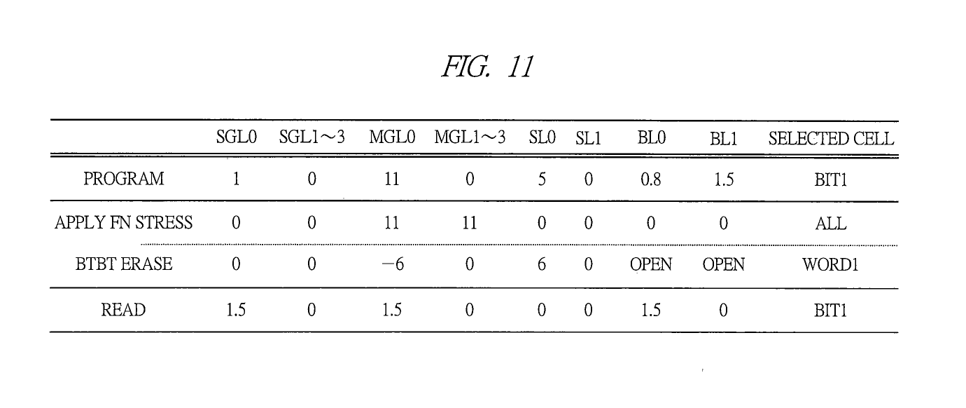

FIG. 10 is a circuit diagram showing a memory array according to the first embodiment. For simplification, only 2×4 memory cells are shown in FIG. 10.

As shown in FIG. 10, select gate lines (word lines) SGL0 to SGL3 connecting the select gate electrode SG of each of the memory cells (memory cells BIT1, BIT2 and the like), memory gate lines MGL0 to MGL3 connecting the memory gate electrode MG and source lines SL0 and SL1 connecting the source region MS shared by two adjacent memory cells extend in parallel to an X direction.

And, bit lines BL0 and BL1 connecting the drain region MD of the memory cells extend in a Y direction, that is, a direction orthogonal to the select gate lines SGL0 to SGL3.

Note that, these lines are configured so as to extend in the above described directions not only in the circuit diagram but also in a layout of elements and lines. And, the select gate lines SGL0 to SGL3 and the like may be composed of the select gate electrode SG or lines connected to the select gate electrode SG. WORD1 to WORD4 shown in FIG. 10 represent erase blocks at erase.

Although not shown in FIG. 10, to the source lines LS0, SL1 and the like and the memory gate lines MGL0 to MGL3 and the like, a boost driver composed of a high voltage MOS transistor for applying a high voltage at the program and the erase is connected. And, to the select gate lines SGL0 to SGL3 and the like, a low voltage and high speed boost driver is connected since only a low voltage of approximately 1.5V is applied. The bit lines BL0, BL1 and the like represent local bit lines. To one local bit line, 16, 32 or 64 pieces of memory cells are connected and the local bit line is connected to a global bit line via a MOS transistor selecting a local bit line. The global bit line is connected to a sense amplifier.

FIG. 11 is a diagram showing conditions of voltages applied to each line at the program, the erase and the read in the memory array shown in FIG. 10.

First, the program operation under the conditions of the voltages shown in FIG. 11 is explained. To perform the program, a necessary condition is that a current flow in the channel, that is, the select transistor is in an ON state.

Program conditions shown in FIG. 11 are those when the memory cell BIT1 shown in FIG. 10 is selected. The select gate line SGL0 is boosted from 0V to near 1.0V and only the bit line BL0 is stepped down from 1.5V to a voltage near 0.8V. Then, 5V is applied to the source line SL0 having the memory cell BIT1 as the selected cell is connected, and 11V is applied to the memory gate line MGL0. As a result, only in the memory cell BIT1 shown in FIG. 10, potential of the select gate line SGL0 becomes higher than potential of the bit line BL0 and the select transistor transits to an ON state, and as a result, the program conditions shown in FIG. 2 is satisfied and the program is performed.

At this time, potential of 1.0V is also applied to the select gate electrodes SG of other memory cells such as BIT2 which are connected to the select gate line SGL0 having the memory cell BIT1 connected. To the bit lines such as BL1 connected to the other memory cells such as BIT2, potential (1.5V, in FIG. 11) higher than the potential (1.0V) of the select gate line SGL0 is applied. By doing so, the select transistor transits to an OFF state in the other memory cells such as BIT2, and the program is not performed.

Next, the erase operation under the conditions of the voltages shown in FIG. 11 is explained. First, in the FN stress application, 11V is applied to all memory gate lines MGL0 to MGL3, and all of other lines such as the select gate lines SGL0 to SGL3, the source lines SL0 and SL1 and the bit lines BL0 and BL1 are set to 0V. By doing so, the FN stress application is performed to all of the memory cells. As explained in FIG. 2, the bit lines BL0 and BL1 may be in the floating state in the same manner as in the BTBT erase. And, to the select gate lines SGL0 to SGL3, 1.5V can be applied.

In the BTBT erase thereafter, all of the bit lines BL0 and BL1 are set to be in the floating state and the select gate lines SGL0 to SGL3 are set to 0V. Then, 6V is applied to the source line SL0 and −6V is applied to the memory gate line MGL0. By doing so, the BTBT erase is performed in the memory cells BIT1 and BIT2 of the WORD1 having the source line SL0 and the memory gate line MGL0 connected.

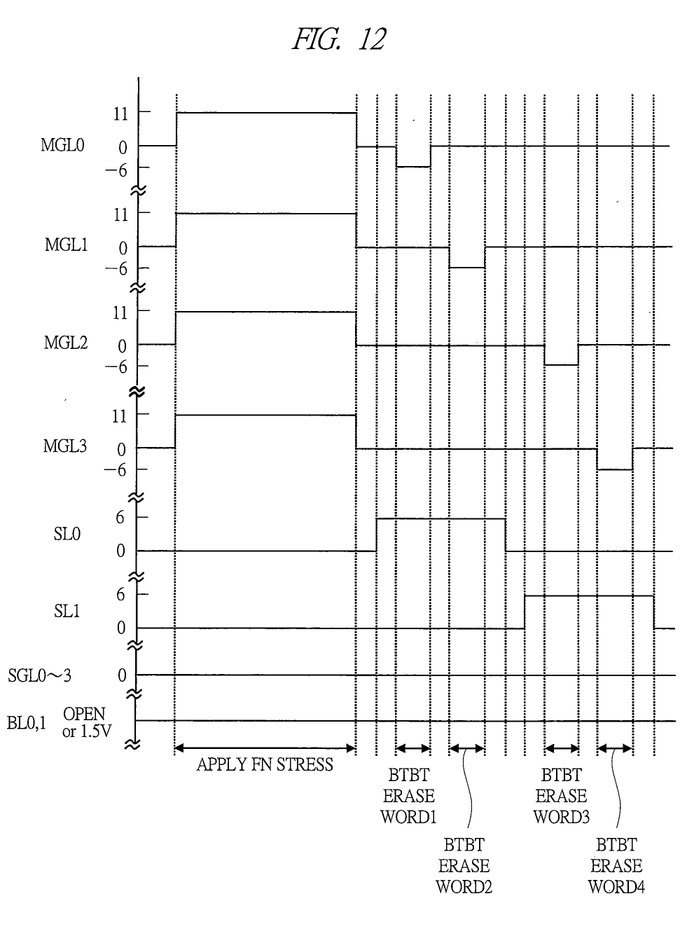

FIG. 12 is a diagram showing an example of a voltage application sequence in the erase operation according to the first embodiment. First, the FN stress is applied to all memory cells collectively. 11V is applied to all of the memory gate lines MGL0 to MGL3, and the source lines SL0 and SL1 and the select gate lines SGL0 to SGL3 are set to 0V. Although the bit lines BL0 and BL1 can be set to 0V, if they are made to be in the floating state similarly to the BTBT erase, voltage switching in transition from the FN stress application to the BTBT erase becomes unnecessary. A FN stress application time is defined as a time in which the threshold voltage is decreased to an expected level by checking a relation between a voltage application time and an amount of decrease of the threshold voltage in advance. For example, setting is performed so that a voltage of 11V is applied to the memory gate lines MGL0 to MGL3 for a time of 30 ms. Operation of verification of the threshold voltage after the FN stress application is preferably not performed since the total erase time is increased. Note that, if a velocity of decrease of the threshold voltage by the FN stress application significantly depends on the number of reprogram times, a sequence in which the operation of the verification of the threshold voltage is performed after the FN stress application and the FN stress application is repeated until the threshold voltage reaches an expected threshold voltage may be employed.

After the FN stress application, the BTBT erase is performed sequentially taking a plurality of memory cells sharing the same memory gate line and the same source line as a unit. In the voltage application sequence shown in FIG. 12, the WORD1 to the WORD4 shown in FIG. 10 are taken as an erase unit of the BTBT erase (erase block). First, in order to perform the BTBT erase to the memory cells of the WORD1, the select gate lines SGL0 to SGL3 are set to 0V and the bit lines BL0 and BL1 are set to the floating state or 1.5V. Then, 6V is applied to the source line SL0 and −6V is applied to the memory gate line MGL0.

To the source line SL1 and the memory gate lines MGL1 to MGL3 having the memory cells of the WORD1 are not connected, a high voltage is not applied and they are set to 0V. In this way, the BTBT erase is performed by changing memory cells to be subjected to the BTBT erase sequentially, such as, after application of a voltage for the BTBT erase to the memory cells of the WORD1, the BTBT erase is performed to the memory cells of the WORD2, then, to the memory cells of the WORD3, and then, to the memory cells of the WORD4. A voltage application time for performing one BTBT erase is set to 100 μs, for example.

After the BTBT erase of a series of the memory cells from the WORD1 to the WORD4, the verification operation checking whether the threshold voltage is decreased to a specified erase level is performed. If the verification operation is not passed, the BTBT erase is repeated until the verification is passed. In this method, since a memory cell in the high threshold state is not left after a first series of the BTBT erase is performed, the erase current flowing through the unselected memory cells at the BTBT erase of a second time and thereafter (the erase current flowing the memory cells of the WORD2 connected to the common source line SL0 when the memory cells of the WORD1 is erased) is decreased and the BTBT erase with the smaller erase current can be performed. That is, in the BTBT erase, when the BTBT erase is performed to the memory cells of the WORD1, for example, the erase current flows through the memory cells of the WORD1, as a matter of course. At this time, the erase current also flows through the memory cells of the WORD2 connected to the source line SL0 which is the common source line with the memory cells of the WORD1. The memory cells of the WORD2 are not objectives of the BTBT erase. However, if the number of memory cells connected to the source line SL0 common with the memory cells subjected to the BTBT erase is increased, even if the erase current flowing through each memory cell which is not an objective of the BTBT erase is smaller than the erase current of the memory cells as the objectives of the BTBT erase, a total of the erase currents becomes large.

Therefore, as described above, if the BTBT erase is performed sequentially to the series of memory cells of the WORD1 to the WORD4, an advantage that the threshold voltages of the memory cells of the WORD1 to the WORD4 are decreased can be obtained. Then, if the verification operation is not passed, the BTBT erase is performed again sequentially to the series of memory cells of the WORD1 to the WORD4. At this time, for example, when the BTBT erase is performed to the memory cells of the WORD1 for a second time, the erase current flows also through the unselected memory cells of the WORD2 connected to the source line SL0 common with the memory cells of the WORD1. However, since the BTBT erase for the first time is performed also to the WORD2 to the WORD4, threshold voltages of the memory cells of the WORD2 which are not the objectives of the BTBT erase are decreased to some degrees. From this, when the BTBT erase is performed to the memory cells of the WORD1 for the second time, since the threshold voltages of the memory cells of the WORD2 to the WORD4 are decreased to some degrees, the erase currents flowing through the memory cells which are not the objectives of the BTBT erase can be decreased. According to this method, in combination with decrease of the erase current by the FN stress application, a further decrease of the erase current can be achieved.

That is, there is a method in which the BTBT erase and the verification operation are repeated until the erase is completed for one BTBT erase block, and the BTBT erase is performed to another erase block after the erase is completely performed to the one BTBT block. In this case, for example, until the erase of the memory cells of the WORD1 is completed, the BTBT erase is not performed to the other memory cells of the WORD2 to the WORD4. In this case, the BTBT erase is performed to the memory cells of the WORD1 while the threshold voltages of the memory cells of the WORD2 to the WORD4 are not sufficiently decreased. Therefore, when the BTBT erase is performed to the memory cells of the WORD1, the erase current flowing the memory cells of the WORD2, which is not the objectives of the BTBT, connected to the source line SL0 common with the memory cells having the BTBT erase performed may be increased. However, even in this method, since the FN stress application is performed to all memory cells, decrease of the erase current by the FN stress application is achieved.

As the unit of the BTBT erase, the memory cells connected to one memory gate line are used in the erase sequence shown in FIG. 12. Alternatively, the memory cells connected to a plurality of memory gate lines may be used. For example, in a case where the memory cells connected to two memory gate lines are used as the unit of the BTBT erase, the BTBT erase is performed simultaneously to the WORD1 and the WORD2, and, the WORD3 and the WORD4. If more memory cells are erased at one time, although a charge pump circuit with higher current supply capability is required and a charge pump circuit having a larger area is required, a time required for the erase can be reduced. That is, according to the first embodiment, since the BTBT erase is performed after the FN stress application, the erase current can be reduced. From this, the charge pump circuit can be downsized. On the contrary, if the charge pump circuit with the same current supply capability is used, the erase current flowing through each memory cell is decreased, and therefore, more memory cells can be collectively BTBT-erased. Accordingly, a time required for erasing all memory cells can be reduced.

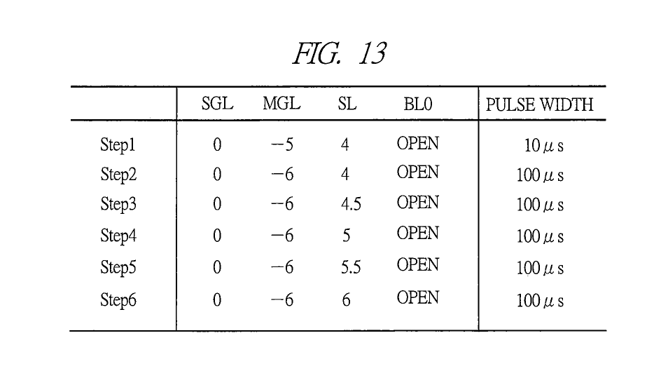

FIG. 13 shows conditions of voltages applied for further decreasing the BTBT erase current in addition to decreasing the BTBT erase current by the FN stress application. In voltage application conditions shown in FIG. 13, an absolute value of a voltage applied to the memory gate line MGL and an absolute value of a voltage applied to the source line SL are increased stepwise as the BTBT erase proceeds. A low voltage is applied in a state where the threshold voltage is high at an initial stage of the BTBT erase and the large erase current flows. When the threshold voltage is decreased by the BTBT erase, a high voltage is applied. By doing so, effects that the large erase current flowing in a state where the threshold voltage is high can be decreased and large decrease of an erase velocity can be prevented by applying a high voltage (absolute value) to the memory gate line MGL and the source line SL after the threshold voltage is decreased can be obtained.

That is, in the voltage application conditions for the BTBT erase shown in FIG. 13, it is assumed that the BTBT erase is performed for a plurality of times to each memory cell. For example, in FIG. 13, the BTBT erase is performed with being divided into six times of Step 1 to Step 6. Here, as the BTBT erase is repeated, the absolute value of the voltage applied to the memory gate line MGL and the absolute value of the voltage applied to the source line SL are increased. By doing so, in the first BTBT erase, since the threshold voltage of the memory cell is not sufficiently decreased, the absolute value of the voltage applied to the memory gate line MGL and the absolute value of the voltage applied to the source line SL are made low to suppress increase of the erase current. Then, as the BTBT erase is repeated, the threshold of the memory cell is sufficiently decreased sufficiently and the increase of the erase current can be suppressed. As a result, the absolute value of the voltage applied to the memory gate line MGL and the absolute value of the voltage applied to the source line SL are increased to increase the erase velocity. For example, in the Step 1, times of applying the voltage to the memory gate line MGL and applying the voltage to the source line SL are 10 μs. In the Step 2 to the Step 6, the times of applying the voltage to the memory gate line MGL and applying the voltage to the source line SL is 100 μs.

Next, the read operation under the voltage conditions shown in FIG. 11 is described.

When the memory cell BIT1 is selected for the read, voltages of the select gate line SGL0, the bit line BL0 and the memory gate line MGL0 connected to the memory cell BIT1 as the selected cell are set to 1.5V, voltages of the select gate lines SGL1 to SGL3, the bit line BL1 and the memory gate lines MGL1 to MGL3 not connected to the memory cell BIT1 are set to 0V, and voltages of all of the source lines SL0 and SL1 are set to 0V. Then, the select transistor of the memory cell BIT1 as the selected cell transits to an ON state and the read operation is performed. The voltage of the memory gate line MGL0 of the memory cell BIT1 is set to 1.5V to obtain the larger read current, but it may be set to 0V to avoid read disturbance.

Under the conditions described above, the electric field between the source region MS and the drain region MD is in a direction reverse to that in the program, but the read in the same direction can also be performed. In this case, potential of the select gate line SGL0 is set to 1.5V and that of the bit line BL0 is set to 0V. These lines are connected to the memory cell BIT1. Potential of the select gate lines SGL1 to SGL3 is set to 0V and that of the bit line BL1 is set to 1.5V. These lines are not connected to the memory cell BIT1. Potential of all of the source lines SL0 and SL1 is set to 1.5V. Accordingly, such a read can be performed.

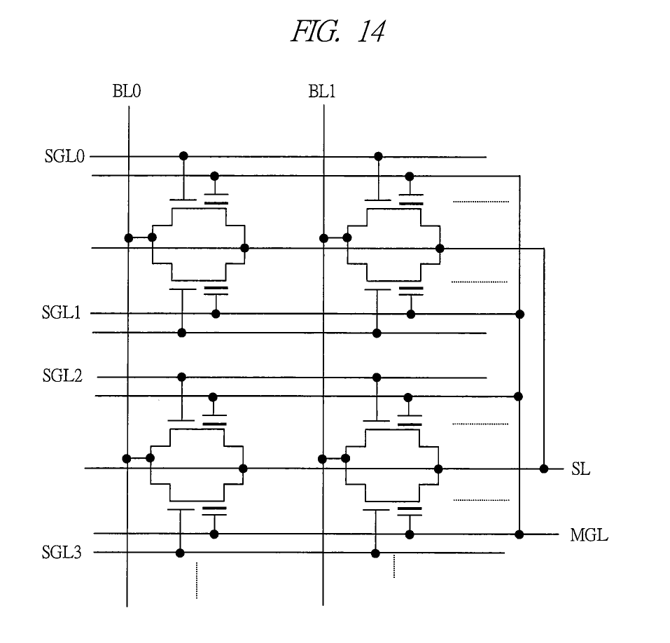

Next, another memory array configuration according to the first embodiment is described. FIG. 14 is a circuit diagram showing another memory array according to the first embodiment. In contrast to the memory array configuration shown in FIG. 10, in the memory array shown in FIG. 14, a plurality of source lines are connected to form a common source line SL. And, a plurality of memory gate lines is connected to form a common memory gate line MGL. By forming the source line SL and the memory gate line MGL in common forms, the number of high voltage drivers driving respective lines can be decreased and a chip area can be decreased. Sharing of lines forming a memory cell array may be performed for one of the source line SL and the memory gate line MGL.

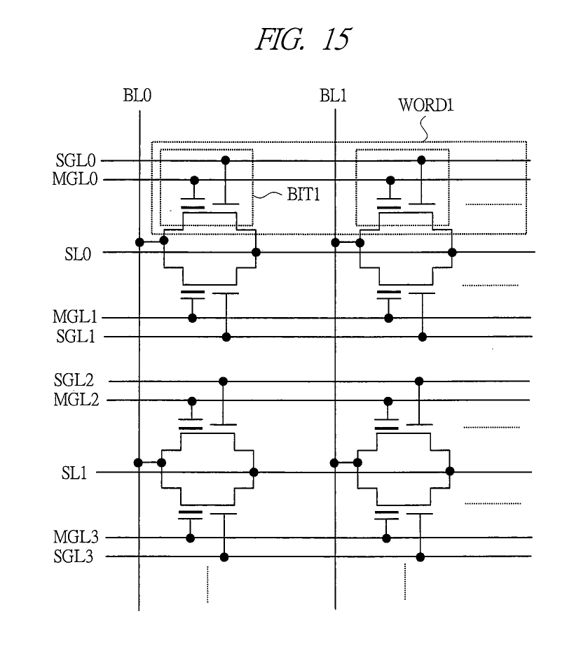

Furthermore, still another memory array configuration according to the first embodiment is described. FIG. 15 is a circuit diagram showing another memory array according to the first embodiment. In comparison with the memory array configuration shown in FIG. 10, in the memory array shown in FIG. 15, the memory transistor and the select transistor are interchanged in position, a bit line BL is connected to a diffusion layer (drain region MD) on a memory transistor side and the source line SL is connected to the diffusion layer (source region MS) on a select transistor side.

Application voltages at the program, the erase and the read operation in the memory array shown in FIGS. 14 and 15 are basically the same as those in the memory array shown in FIG. 10. The operation is performed by applying the same voltages as the voltages shown in FIG. 11 to the selected cell and the unselected cell.

In the above, although operation voltage conditions of the memory cell and the memory array are described with reference to FIGS. 2, 11, 12 and 13, these conditions are merely examples, and numerical values described herein do not restrict the present invention.

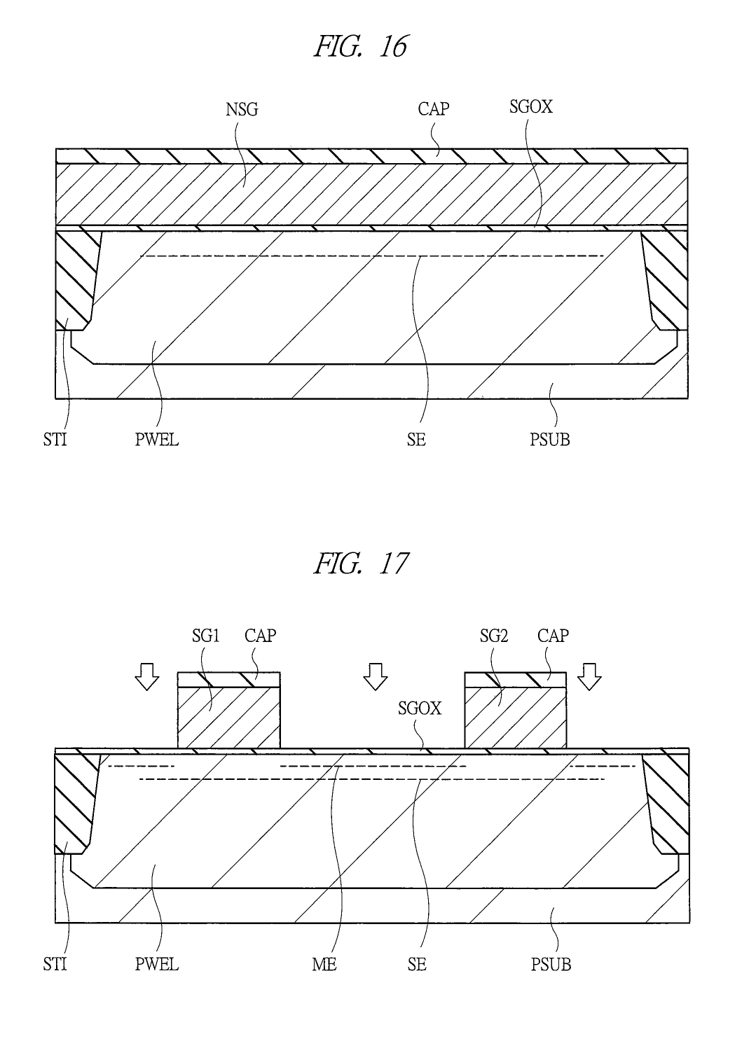

Next, one example of a manufacturing method of the non-volatile semiconductor memory device (memory cell) shown in FIG. 1 is described with reference to FIGS. 16 to 23. FIGS. 16 to 23 are cross-sectional views of main portions of the non-volatile semiconductor memory device in its manufacturing process according to the first embodiment. In each diagram, a cross-sectional view of two memory cell regions sharing the source region MS is shown.

First, FIG. 16 is described. An isolation region STI is formed over the semiconductor substrate PSUB composed of a p-type silicon substrate to form the p-type well region PWEL as a memory cell region.

In a surface portion of this p-type well region PWEL, a p-type impurity region (channel region) SE adjusting the threshold of the select transistor is formed. Next, after a cleaning processing is performed to a surface of the semiconductor substrate PSUB, the gate dielectric film SGOX of the select transistor is formed by thermal oxidation, and an n-type polysilicon layer NSG as the select gate electrode (approximately 100 nm) and a silicon oxide film CAP for protecting the select gate electrode are sequentially deposited over the SGOX.

Next, FIG. 17 is described. Using a photolithography technique and a dry etching technique, the n-type polysilicon layer NSG formed over the semiconductor substrate PSUB in FIG. 16 is processed to form the select gate electrodes SG1 and SG2 of the select transistor. These select gate electrodes SG1 and SG2 extend in a depth direction of the diagram and form a linear shaped pattern. This pattern shape corresponds to the select gate line SGL of the memory array (see FIG. 10 and the like). Note that, when this pattern shape is being formed, dry etching is stopped at a stage where a surface of the gate dielectric film SGOX is exposed in order to prevent unwanted damage on the surface of the semiconductor substrate PSUB. Then, an n-type impurity region ME for adjustment of the threshold is formed in a channel region of the memory transistor over the surface of the semiconductor substrate PSUB. For example, impurity density of the n-type impurity region ME is approximately 1'10¹²/cm².

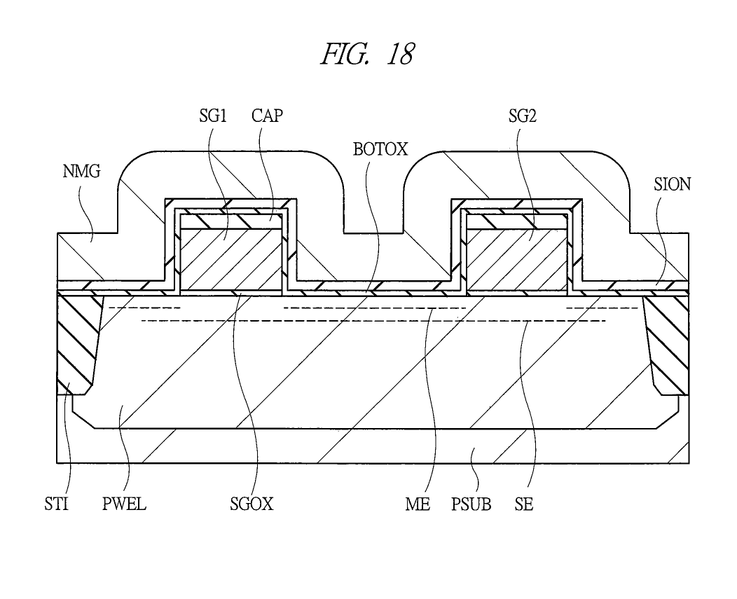

Next, FIG. 18 is described. The gate dielectric film SGOX left for protecting the surface of the semiconductor substrate PSUB in FIG. 17 is removed by the fluorinated acid, and the bottom silicon oxide film BOTOX and the silicon oxynitride film SION to be the gate dielectric film of the memory transistor are laminated. Note that, when the gate dielectric film SGOX is being removed, the silicon oxide film CAP formed over the select gate electrodes SG1 and SG2 may be removed together.

To form the bottom silicon oxide film BOTOX and the silicon oxynitride film SION to be the gate dielectric film of the memory transistor, for example, after the bottom silicon oxide film BOTOX (approximately 3 nm to 10 nm) is formed by the thermal oxidation or ISSG (In-situ Stream Generation) oxidation, the silicon oxynitride film SION (approximately 5 to 30 nm) is deposited by a decompression chemical vapor deposition method. Here, a thickness of the bottom silicon oxide film BOTOX is preferably 3 nm or larger, in which the tunneling phenomenon is hard to occur.

Then, over a multilayered film of the bottom silicon oxide film BOTOX and the silicon oxynitride film SION, an n-type polysilicon layer NMG (approximately 100 nm) to be the memory gate electrode is deposited.

Next, FIG. 19 is explained. By an anisotropic etching technique, the n-type polysilicon layer NMG deposited in FIG. 18 is removed until the silicon oxynitride film SION is exposed, and the memory gate electrodes MG1 and MG2 are formed over side walls of the select gate electrodes SG1 and SG2 via the bottom silicon oxide film BOTOX and the silicon oxynitride film SION. A spacer width of these memory gate electrodes MG1 and MG2 is preferably set to 40 to 90 nm. At this time, a side-wall spacer MCP formed of a polysilicon film is formed over side walls of the select gate electrodes SG1 and SG2 opposite to the memory gate electrodes MG1 and MG2.

Next, in order to remove the side-wall spacer MGR, the memory gate electrodes MG1 and MG2 are covered by a photoresist film RES1 using the photolithography technique. At this time, the photoresist film RES1 is formed so that an end of the photoresist film RES1 is over the select gate electrodes SG1 and SG2.

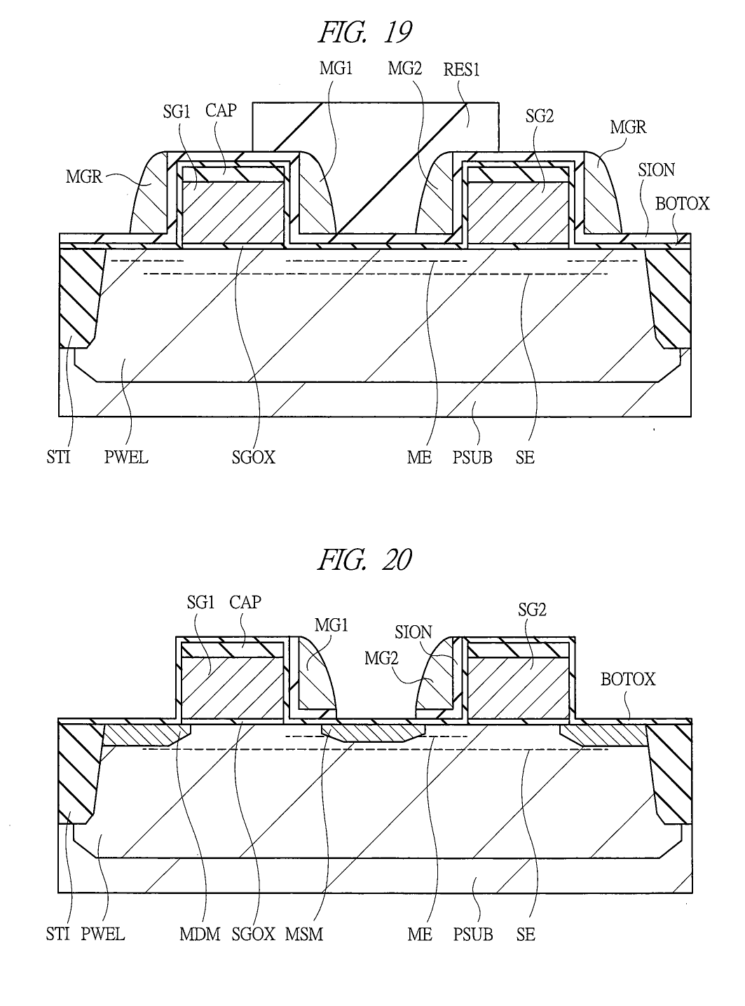

Next, FIG. 20 is explained. The side-wall spacer MGR composed of the polysilicon film formed in FIG. 19 is removed by the dry etching technique and the photoresist film RES1 is further removed. Thereafter, the exposed silicon oxynitride film SION is removed by hot phosphoric acid. Then, low-density n-type impurities are ion-implanted into the semiconductor substrate PSUB to form a low-density n-type impurity region MDM. In this ion implantation, a low-density n-type impurity region MSM is also formed. Low-density n-type impurity regions MDM and MSM may be formed separately by the photolithography technique and resist films.

A reason why the side-wall spacer MGR formed of the polysilicon film is removed in FIG. 20 is to form the low-density n-type impurity region MDM. For example, in FIG. 17, after the n-type impurity region ME is formed, if an upper portion of the source region is covered by a photoresist film using the photolithography technique and the low-density n-type impurity region MDM is formed, the side-wall spacer MGR formed of the polysilicon film does not have to be removed.

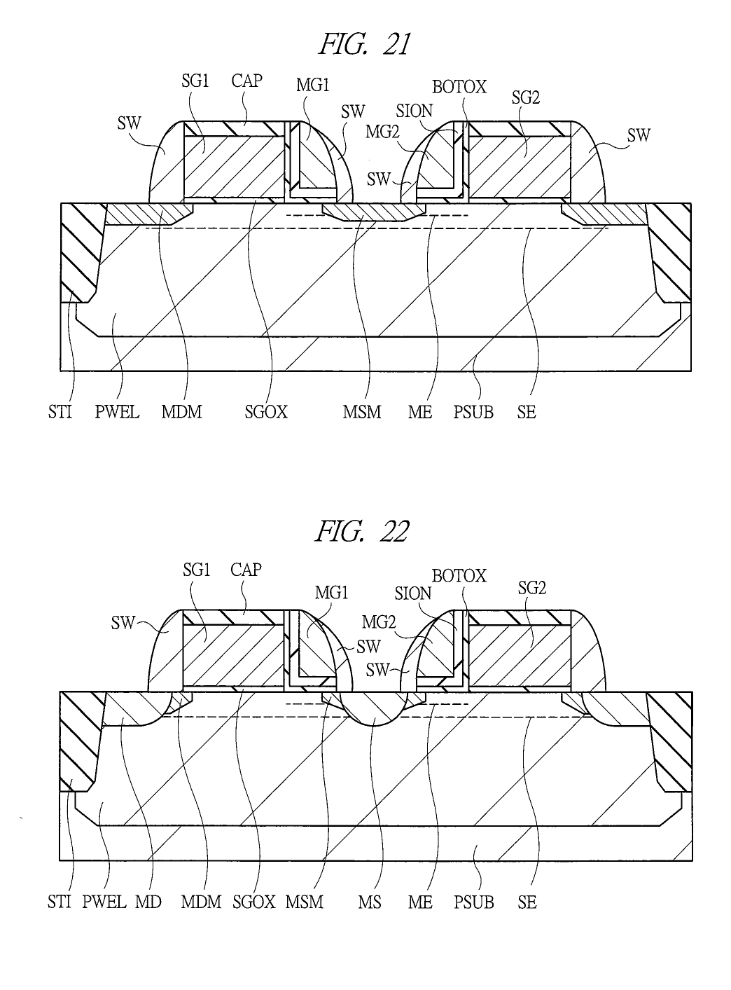

Next, FIG. 21 is described. After a portion of the bottom silicon oxide film BOTOX exposed to the surface is removed by the fluorinated acid, the silicon oxide film is deposited and etching is performed by the anisotropic etching technique, and as a result, side-wall spacers SW are formed over side walls of the select gate electrodes SG1 and SG2 and side walls of the memory gate electrodes MG1 and MG2.

Next, FIG. 22 is described. n-type impurities are ion-implanted into the semiconductor substrate PSUB to form the drain region MD of the select transistor and the source region MS of the memory transistor. Here, although descriptions such as the drain region MD and the source region MS are made, the drain region is formed of the drain region MD and the low-density n-type impurity region MDM, and the source region is formed of the source region MS and the low-density n-type impurity region MSM.

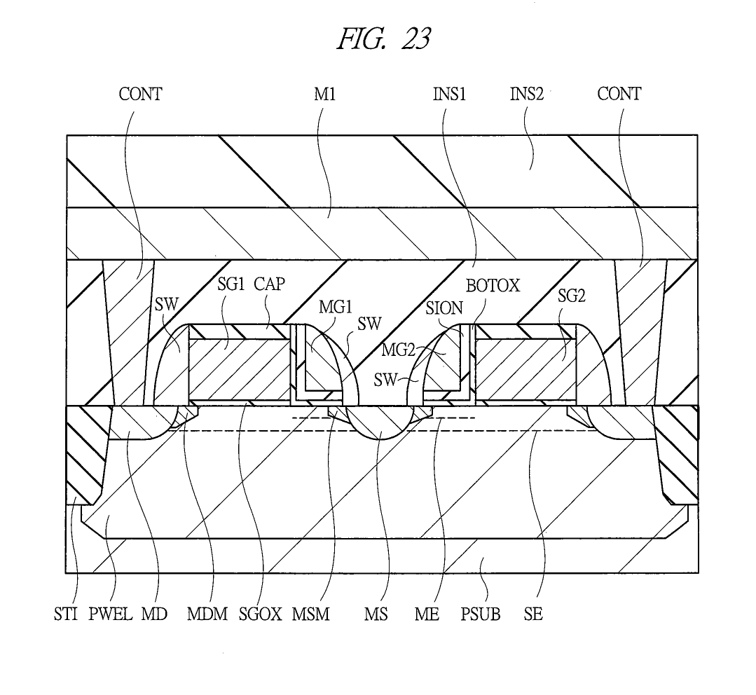

Next, FIG. 23 is described. An interlayer dielectric film INS1 is deposited over an entire surface of the semiconductor substrate PSUB. Then, using the photolithography technique and the dry etching technique, a contact hole is opened over the drain region MD, and a plug CONT made of a metal layer is deposited in an opening portion. Then, using the photolithography technique and the etching technique, a first metal line M1 electrically connected to the plug CONT is formed over the interlayer dielectric film INS1.

As shown in FIG. 23, the memory gate electrodes MG1 and MG2 and the select gate electrodes SG1 and SG2 extend in a direction perpendicular to a paper surface, for example, and are connected to the drain region MD. The first metal line M1 to be the bit line BL extends in a direction orthogonal to the memory gate electrodes MG1 and MG2 and the select gate electrodes SG1 and SG2 (see FIG. 10). Note that, in a case of the circuit diagram shown in FIG. 15, the memory gate electrodes MG1 and MG2 and the select gate electrodes SG1 and SG2 are interchanged in position.

Then, an interlayer dielectric film INS2 is deposited over the first metal line M1. Thereafter, although not shown in diagrams, a plug is formed in the interlayer dielectric film INS2 and a second metal line is further formed by depositing a conductive film and patterning the same. As described above, by repeating formation processings of the interlayer dielectric film and the line, a multilayered line can be formed. In this manner, the non-volatile semiconductor memory device according to the first embodiment can be manufactured.

Next, another split-gate-type memory cell realizing the erase method according to the first embodiment is described with reference to FIGS. 24 to 26. FIGS. 24 to 26 are cross-sectional views of main portions of another non-volatile semiconductor memory device (memory cell) according to the first embodiment.

FIG. 24 shows a memory cell having the select gate electrodes SG formed in a shape of the side-wall spacer of the memory gate electrode MG. In such a memory cell, the bottom silicon oxide film BOTOX, the silicon oxynitride film SION and the memory gate electrode MG of the memory transistor are formed in advance, and then, a side-wall spacer GAPSW formed of the dielectric film is formed over side walls thereof. Furthermore, over the side walls thereof, the select gate electrode SG is formed by the anisotropic etching technique in the same manner as the memory gate electrode MG of the memory cell described with reference to FIG. 1 and the like.

Note that, by forming the side-wall spacer GAPSW with an oxide film thicker than that of the gate dielectric film SGOX of the select transistor, a withstand voltage between the memory gate electrode MG and the select gate electrode SG can be improved.

And, impurity implantation of the channel region (n-type impurity region) under the memory gate electrode MG and impurity implantation of the channel region (p-type impurity region) under the select gate electrode are performed before and after formation of the memory gate electrode MG, respectively.

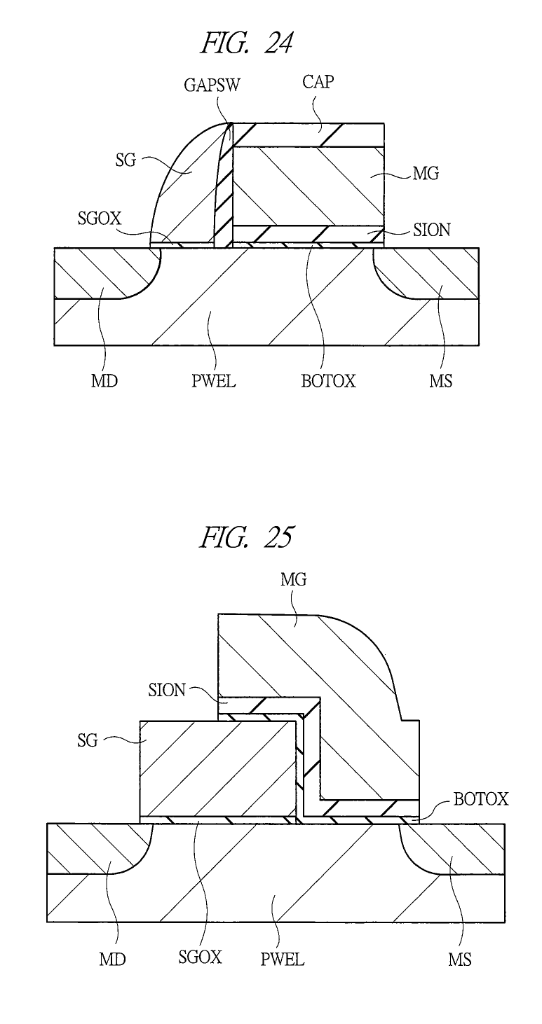

FIG. 25 shows a memory cell having a configuration in which the memory gate electrode MG is placed over the select gate electrode SG. In such a memory cell, in the same manner as the memory cell described with reference to FIG. 1 and the like, the select gate electrode SG is formed in advance, and the bottom silicon oxide film BOTOX, the silicon oxynitride film SION and the memory gate electrode MG are formed using the photolithography technique. Impurity implantation of the channel region (n-type impurity region) of the memory transistor and impurity implantation of the channel region (p-type impurity region) of the select transistor are performed in the same manner as the case described with reference to FIGS. 16 and 17.

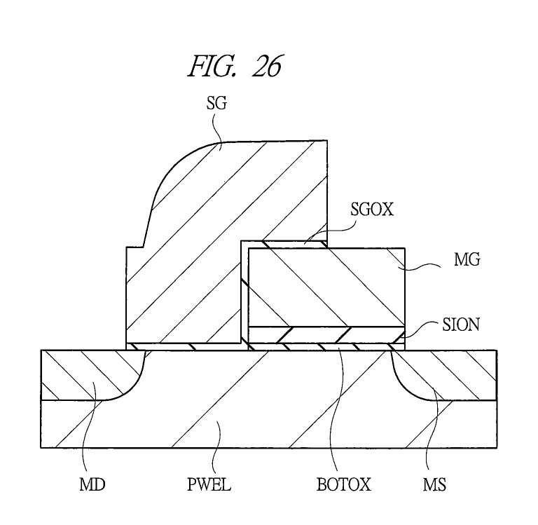

FIG. 26 shows a memory cell having a configuration in which the select gate electrode SG is placed over the memory gate electrode MG. Such a memory cell can be formed in the same manner as the memory cell shown in FIG. 24, except that the select gate electrode SG is formed by the photolithography technique. That is, after the bottom silicon oxide film BOTOX, the silicon oxynitride film SION and the memory gate electrode MG are formed in advance, the select gate electrode SG is formed. Impurity implantation of the channel region (n-type impurity region) of the memory transistor and impurity implantation of the channel region (p-type impurity region) of the select transistor are performed before and after formation of the memory gate electrode MG, respectively.

As described above, also in the memory cell configurations shown in FIGS. 24 to 26, operation similar to that of the memory cell shown in FIG. 1 can be performed using the memory arrays and the voltage conditions shown in FIGS. 2 to 15.

### Second Embodiment

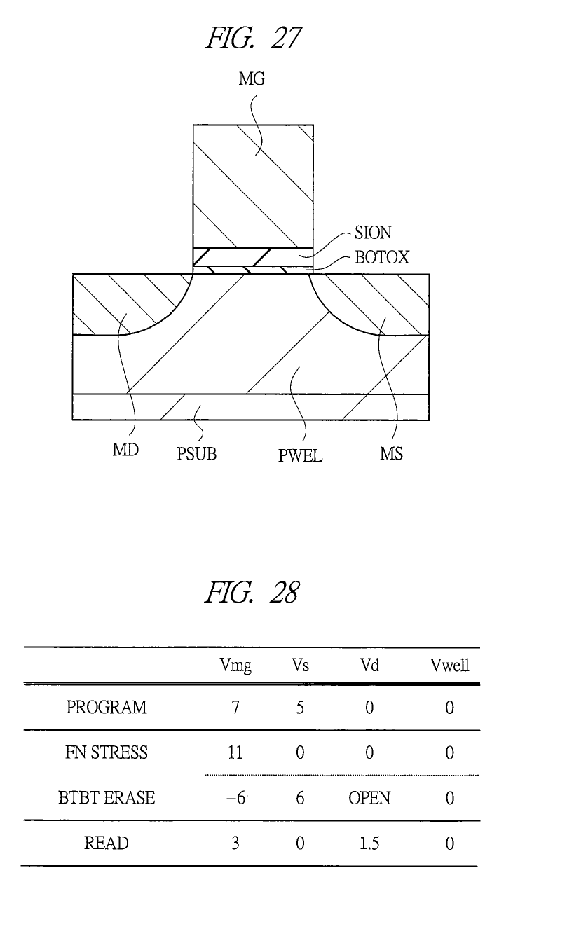

FIG. 27 is a cross-sectional view of main portions of a representative non-volatile semiconductor memory device (memory cell) according to a second embodiment. A memory cell of the non-volatile semiconductor memory device shown here is a single-gate-type cell using a charge-trapping dielectric film as the charge accumulation film.

As shown in FIG. 27, the memory cell comprises the silicon oxynitride film SION as the charge accumulation film, the gate dielectric film composed of the bottom silicon oxide film BOTOX positioned therebelow, and the memory gate electrode MG composed of a conductor such as the n-type polysilicon film. And, the memory cell also includes the source region (source diffusion layer, n-type semiconductor region) MS composed of the semiconductor region (silicon region) having the n-type impurities implanted therein and the drain region (drain diffusion layer, n-type semiconductor region) MD composed of the semiconductor region (silicon region) having the n-type impurities implanted therein. The source region MS and the drain region MD are formed in the p-type well region PWEL provided over the semiconductor substrate PSUB composed of the p-type silicon substrate.

In the same manner as the memory cell according to the first embodiment, in order to facilitate injection of holes from the memory gate electrode MG into the charge accumulation film when the FN stress application is performed, the silicon oxynitride film SION is used in place of the silicon nitride film as the charge accumulation film, a configuration in which the silicon oxynitride film SION directly contacts with the memory gate electrode MG and the top silicon oxide film is not provided is employed. With this configuration, the amount of the hole injection from the memory gate electrode MG into the silicon oxynitride film SION as the charge accumulation film can be increased and the threshold voltage of the memory cell can be decreased efficiently. And, because of high charge retention capability of the silicon oxynitride film SION, the excellent data retention characteristic can be obtained without the top silicon oxide film.

And, in the same manner as the memory cell according to the first embodiment, in order to ensure a sufficient amount of charge accumulation, a configuration in which the silicon nitride film is laminated in the silicon oxynitride film SION or between the silicon oxynitride film SION and the bottom silicon oxide film BOTOX may be employed. And, in order to obtain the more excellent data retention capability, the top silicon oxide film having a film thickness of 3 nm or smaller in which the tunneling phenomenon causing injection of positive holes from the memory gate electrode MG into the charge accumulation film may be provided. If the top silicon oxide film is provided, the injection of holes by the tunneling phenomenon can be performed effectively by interposing a nano-conductive particle, a silicon nitride film or an amorphous thin film in the top silicon oxide film.

Also in the memory gate electrode MG, in the same manner as the memory cell according to the first embodiment, by using the p-type polysilicon film in place of the n-type polysilicon film, and by decreasing n-type impurity density of the n-type polysilicon film, the amount of the hole injection from the memory gate electrode MG into the charge accumulation film when the FN stress application is performed can be increased.

Next, the program operation, the erase operation and the read operation of the memory cell according to the second embodiment are described. FIG. 28 is a diagram showing conditions of voltage application to respective portions of the memory cell at “program”, “erase” and “read”. By performing the program operation and the erase operation with application voltages to the source region MS and the drain region MD in reverse to those of the read operation, the charges are accumulated in two portions, that is, a first localized region on a source side of the silicon oxynitride film SION and a second localized region on a drain side of the same, and two bits/cell operation can be performed. Here, the program operation, the erase operation and the read operation in a case where the charges are accumulated in the first localized region on the source side are explained.

The program operation is performed by a channel-hot-electron (CHE) injection method. As program voltages, for example, a voltage applied to the source region MS can be set to 5V and a voltage applied to the memory gate electrode MG can be set to 7V. And, a voltage applied to the drain region MD is set to 0V and a voltage applied to the p-type well PWEL is set to 0V. Note that, other than the channel-hot-electron injection method, the program operation can be performed by another method such as a channel initiated secondary electron (CHISEL) injection method.

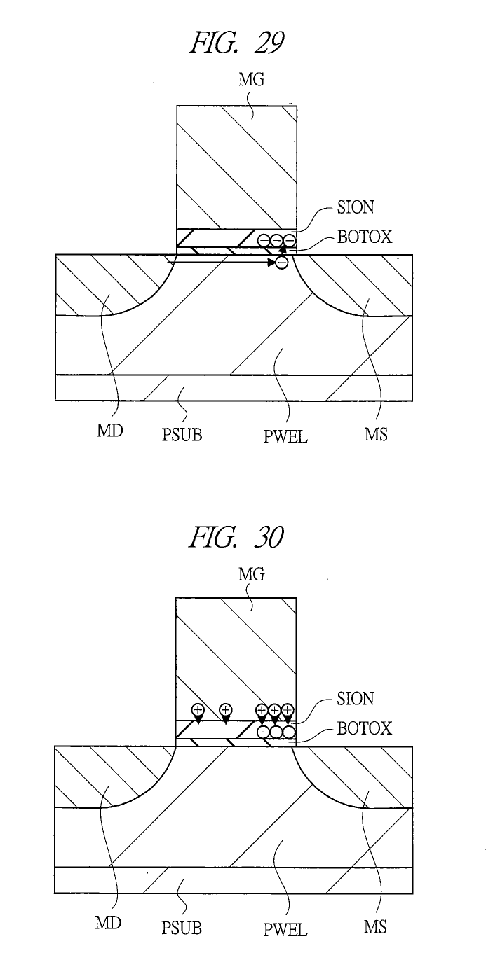

FIG. 29 shows a movement of electrons at the program by the channel-hot-electron injection method. Electrons flowing through the channel are accelerated in a strong electric field at an end of the source region MS caused by application of a high voltage to the source region MS to be hot electrons, and hot electrons are injected into the silicon oxynitride film SION under the memory gate electrode MG by an electric field in the vertical direction caused by a positive voltage applied to the memory gate electrode MG. The injected electrons (hot electrons) are captured at the trap level in the silicon oxynitride film SION. As a result, electrons are accumulated in the silicon oxynitride film SION and the threshold voltage of the memory cell is increased.

Here, in the second embodiment, the program operation is performed using the channel-hot-electron injection method, and on the other hand, in the first embodiment, the source side injection method is used. In either method, hot electrons are generated and then injected into the charge accumulation film, but the conditions of the voltage application to the respective portions of the memory cell are different. Because of difference between the voltage conditions, portions in which electrons are generated are different. In the source side injection method used in the first embodiment, as shown in FIG. 3, hot electrons are generated immediately under a portion in the vicinity of the boundary between the select gate electrode SG and the memory gate electrode MG. On the other hand, in the channel-hot-electron injection method used in the second embodiment, as shown in FIG. 29, it can be seen that hot electrons are generated in the vicinity of the boundary between the p-type well PWEL and the source region MS. By using this channel-hot-electron injection method, electrons can be accumulated in the first localized region on the source side of the silicon oxynitride film SION.

Next, the erase operation is described. A flow of the erase operation is identical to the flowchart shown in FIG. 4 in the first embodiment. After the FN stress application is performed first, BTBT hot-hole erase is repeated until the threshold voltage reaches the set threshold voltage. This is one of features of the second embodiment.

FIG. 30 is a diagram showing a movement of charges at the FN stress application. In the FN stress application, as application voltages, for example, the voltage applied to the memory gate electrode MG is set to 11V, and voltages applied to other portions (the voltage applied to the source region MS, the voltage applied to the drain region MD and the voltage applied to the p-type well PWEL) are all set to 0V. In the FN tunneling phenomenon caused by this FN stress application, as shown in FIG. 30, holes are injected from the memory gate electrode MG into the silicon oxynitride film SION. At this time, in a portion in which electrons are accumulated in the silicon oxynitride film SION in the program operation, the accumulated electrons increase the vertical electric field upon the silicon oxynitride film SION at interface between the memory gate electrode MG and the silicon oxynitride film SION, and therefore, the amount of the hole injection is increased. By this injection of holes, electrons accumulated in the silicon oxynitride film SION by the program operation are decreased and the threshold voltage of the memory cell is decreased. The voltage applied to the drain region MD can be in the floating state, similarly to the case of the BTBT erase in order to make voltage switching at transition to the BTBT erase unnecessary. Change of the threshold voltage of the memory cell by the FN stress application is similar to the characteristic shown in FIG. 6.

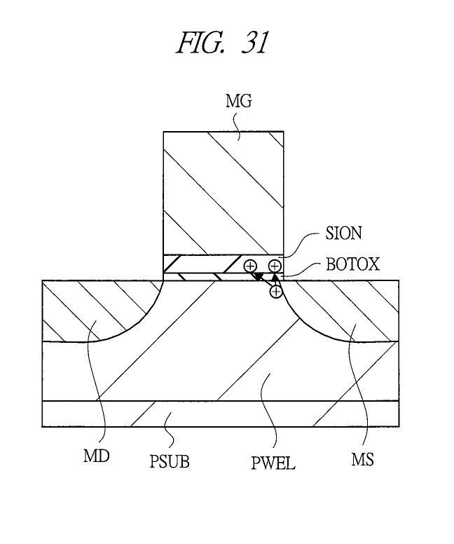

FIG. 31 shows a movement of the charge at the BTBT erase after the FN stress application. In the BTBT erase, for example, the voltage applied to the memory gate electrode MG is set to −6V, the voltage applied to the source region MS is set to 6V and the drain region MD is set to be in the floating state. The holes generated at the end of the source region MS by the voltage between the source region MS and the memory gate electrode MG using the band-to-band tunneling phenomenon are accelerated by the high voltage applied to the source region MS to be the hot holes and a part of the hot holes are drawn to a negative voltage applied to the memory gate electrode MG to be injected into the silicon oxynitride film SION. The injected hot holes are captured at the trap level of the silicon oxynitride film SION and the threshold voltage of the memory cell is decreased. Then, the BTBT erase is repeated until the threshold voltage of the memory cell is sufficiently decreased (until the verification operation is passed). In the BTBT erase, since the hot holes are injected, the charge accumulation film can be made to transit to the positive-charge accumulation state passing through the charge neutral state. Therefore, the threshold voltage of the memory transistor can be sufficiently decreased, the large read current can be obtained, and therefore, an advantage suitable for the high-speed operation can be obtained.

As described above, in the same manner as the first embodiment, also in the second embodiment, because of decrease of the threshold voltage caused by the FN stress application, the electric field in the vertical direction at a position where the band-to-band tunneling phenomenon occurs is decreased, amounts of electrons and holes generated by the band-to-band tunneling are decreased, and therefore, the effect of decreasing the erase current can be achieved in the same manner as the first embodiment.

Next, a read method is described. In the read operation, for example, the voltage applied to the drain region MD is set to 1.5V, the voltage applied to the source region MS is set to 0V and the voltage applied to the memory gate electrode MG is set to 3V. And, the voltage between the source region MS and the drain region MD is set to be reverse to the voltage at the program. Thereby, the read operation can be performed.

Next, operation in a case where the memory array is composed of a plurality of memory cells is described.

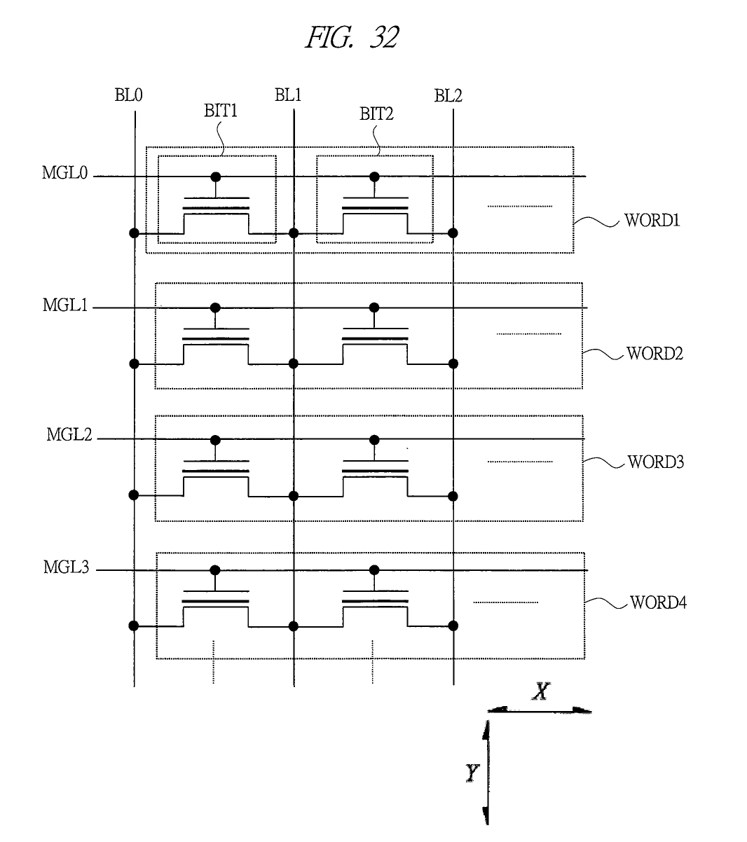

FIG. 32 is a circuit diagram of the memory array according to the second embodiment. For simplification, only a 2×4 memory array is shown. As shown in FIG. 32, in order to perform the two bits/cell operation by taking two portions on the source region MS side and the drain region MD side of the charge accumulation film as localized regions, an array configuration called a bilaterally-symmetric virtual grand array is employed.

As shown in FIG. 32, memory gate lines MGL0 to MGL3 connecting memory gate electrodes MG of respective memory cells extend in parallel to an X direction.

And, bit lines BL0 to BL2 connecting the source region MS and the drain region MD of the memory cell extend in a Y direction, that is, a direction orthogonal to the memory gate lines MGL0 to MGL3. Note that, these lines are configured so as to extend in the above-described directions not only in the circuit diagram but also in a layout of elements and lines.

Although not shown in FIG. 32, to the bit lines BL0 to BL2 and the like and the memory gate lines MGL0 to MGL3 and the like, the boost driver composed of the high voltage MOS transistor for applying the high voltage at the program and the erase is connected. The bit lines BL0 to BL2 and the like configure the local bit lines. To one local bit line, 16, 32 or 64 pieces of memory cells are connected and the local bit line is connected to the global bit line via the MOS transistor selecting a local bit line. The global bit line is connected to the sense amplifier.

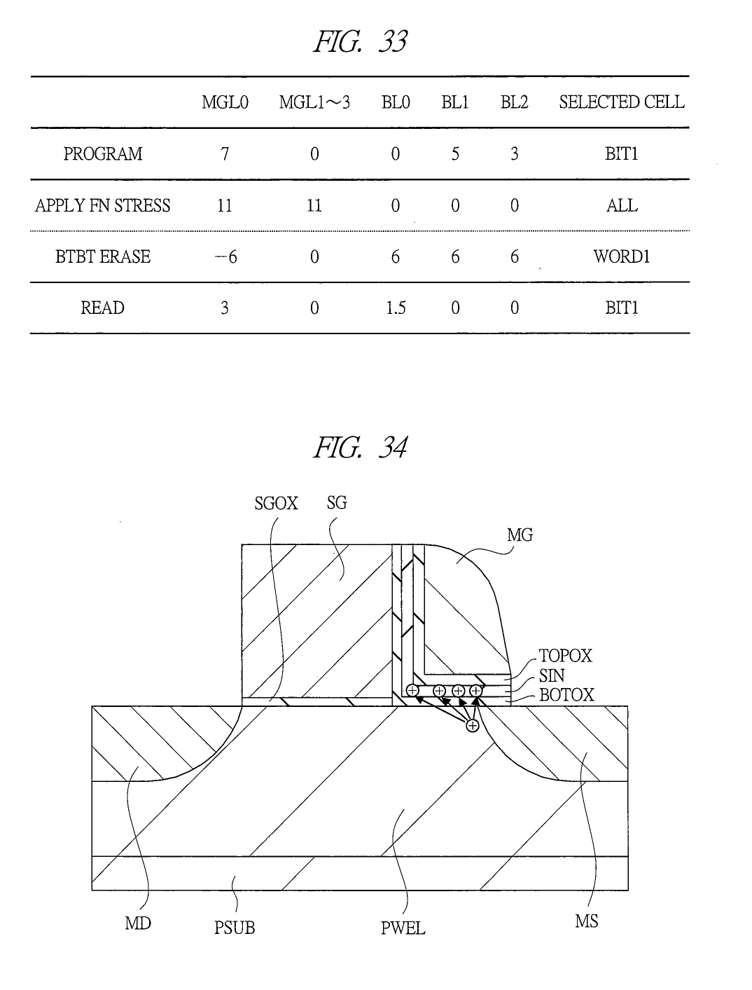

FIG. 33 is a diagram showing conditions of voltage application to each line at the program, the erase and the read in the memory array shown in FIG. 32.

First, the program operation under voltage conditions shown in FIG. 33 is described. Program conditions shown in FIG. 33 are conditions of injecting the charge into a bit line BL1 side of the memory cell BIT1 shown in FIG. 32. 5V is applied to the bit line BL1 connected to a charge injection side of the memory cell BIT1 as the selected cell, 7V is applied to the memory gate line MGL0, and the bit line BL0 connected to a side of the memory cell BIT1 where no charge is injected is set to 0V. As a result, the program conditions shown in FIG. 28 are satisfied and the electron is injected into the charge accumulation film on a bit line BL1 side of the memory cell BIT1, and as a result, the program operation is performed. At this time, in order to prevent the charge from being injected into a bit line BL1 side of the unselected memory cell BIT2, 3V is applied to the bit line BL2 connected to the memory cell BIT2. Other memory gate lines MGL1 to MGL3 to which the selected cell is not connected are set to 0V.

Next, the erase operation under the voltage conditions shown in FIG. 33 is described. After the FN stress application of a predetermined time, the erase operation is performed in a sequence performing the BTBT erase sequentially by a BTBT erase unit. In the first FN stress application, 11V is applied to all of the memory gate lines MGL0 to MGL3 and all bit lines BL0 to BL2 are set to 0V. Under these conditions, the FN stress is applied to all memory cells. In the BTBT erase thereafter, 6V is applied to the bit lines BL0 to BL2 to which memory cells included in the WORD1 are connected and −6V is applied to the memory gate line MGL0. The BTBT erase is performed in the memory cells of the WORD1 where high voltages are applied to both of the bit lines BL0 to BL2 and the memory gate line MGL0. Similarly, the BTBT erase is sequentially performed to the WORD2, the WORD3 and the WORD4.

Next, the read operation under the voltage conditions shown in FIG. 33 is described. When charges accumulated on the bit line BL1 side of the memory cell BIT1 are to be read, 1.5V is applied to the bit line BL0 to which the memory cell BIT1 as the selected cell is connected, 0V is applied to the bit line BL1, and 3V is applied to the memory gate MGL0. The read operation is performed by carrying a current in reverse direction to that in the program.

In the above, although the voltage conditions for driving the memory cell according to the second embodiment are described with reference to FIGS. 28 and 33, these conditions are merely examples and the present invention is not restricted by the numerical values described herein.

A manufacturing method of the non-volatile semiconductor memory device (memory cell) shown in FIG. 27 is identical to a manufacturing method of an NROM (Nitride ROM), except for a method of forming the gate dielectric film of the memory transistor.

To form the gate dielectric film of the memory transistor, after the bottom silicon oxide film BOTOX (approximately 3 nm to 10 nm) is formed by the thermal oxidation or the ISSG (In-situ Stream Generation) oxidation, the silicon oxynitride film SION (approximately 5 to 30 nm) is deposited by the decompression chemical vapor deposition method. Here, a film thickness of the bottom silicon oxide film BOTOX is preferably 3 nm or larger in which the tunneling phenomenon is hard to occur. In this manner, the non-volatile semiconductor memory device according to the second embodiment can be manufactured.

In the foregoing, the invention made by the inventors of the present invention has been concretely described based on the embodiments. However, it is needless to say that the present invention is not limited to the foregoing embodiments and various modifications and alterations can be made within the scope of the present invention.

In the first and second embodiments, as the charge accumulation film of the memory cell, the silicon oxynitride film or the silicon nitride film is used. However, a charge-trapping dielectric film having a trap level, such as a tantalum oxide film or an aluminum oxide film may be used.

And, in the first and second embodiments, as the FN stress application, an example in which holes are injected from the memory gate electrode into the charge accumulation film using the FN tunneling phenomenon is described. This is not meant to be restrictive. For example, electrons accumulated in the charge accumulation film may be decreased by drawing electrons from the charge accumulation film to the memory gate electrode using the FN tunneling phenomenon.

The present invention can be widely used in manufacturing industries manufacturing non-volatile semiconductor memory devices.

What is claimed is:

1. A non-volatile semiconductor memory device comprising:
a memory cell, comprising:
(a) a first semiconductor region and a second semiconductor region formed in a semiconductor substrate so as to be separated from each other;
(b) a first dielectric film formed over an upper portion of the semiconductor substrate over a portion between the first semiconductor region and the second semiconductor region; and
(c) the first gate electrode formed over the first dielectric film,
wherein the first dielectric film comprises:
(b1) a silicon oxide film; and
(b2) the charge accumulation film with a function of accumulating a charge formed over the silicon oxide film and directly contacting with a first gate electrode,
wherein first operation of making a threshold voltage of the memory cell lower than a threshold voltage of the memory cell in a program state is performed by applying a positive voltage larger than a voltage applied to the semiconductor substrate to the first gate electrode, and then second operation of making the threshold voltage of the memory cell still lower is performed by injecting holes generated using a band-to-band tunneling phenomenon in the semiconductor substrate into the charge accumulation film so as to complete erase operation.

2. The non-volatile semiconductor memory device according to claim 1,
wherein the charge accumulation film is a silicon oxynitride film.

3. The non-volatile semiconductor memory device according to claim 1,
wherein the first operation is performed by injecting holes from the first gate electrode into the charge accumulation film.

4. The non-volatile semiconductor memory device according to claim 1,
wherein the non-volatile semiconductor memory device comprises the memory cell plurally in number, and
wherein the first operation is performed to all of the memory cells collectively and then the second operation is performed by a block unit obtained by dividing the all of the memory cells.

5. The non-volatile semiconductor memory device according to claim 1,
wherein the first operation is not repeated and the second operation is repeated until the threshold voltage of the memory cell is decreased to a predetermined threshold voltage.

6. The non-volatile semiconductor memory device according to claim 1,
wherein a voltage applied to the first gate electrode in the first operation is 10V or larger to 12V or smaller.

7. The non-volatile semiconductor memory device according to claim 5,
wherein the second operation is performed by applying a predetermined negative voltage to the first gate electrode and applying a predetermined positive voltage larger than the voltage applied to the semiconductor substrate to the second semiconductor region, and an absolute value of a voltage applied to the first gate electrode and an absolute value of a voltage applied to the second semiconductor region are increased as the second operation is repeated.

8. The non-volatile semiconductor memory device according to claim 1,
wherein program operation of the memory cell is performed by injecting hot electrons into the charge accumulation film by a channel-hot-electron injection method.

9. The non-volatile semiconductor memory device according to claim 1,
wherein information of two bits is stored in one memory cell by independently accumulating charges in a first localized region on a first semiconductor region side of the charge accumulation film and in a second localized region on a second semiconductor region side of the charge accumulation film.

10. The non-volatile semiconductor memory device according to claim 1,
wherein a select transistor selecting the memory cell is formed in the memory cell, and
wherein the select transistor comprises:
(d) a second dielectric film formed over the upper portion of the semiconductor substrate over the portion between the first semiconductor region and the second semiconductor region; and
(e) a second gate electrode formed over the second dielectric film.

11. The non-volatile semiconductor memory device according to claim 10,
wherein program operation of the memory cell is performed by injecting hot electrons into the charge accumulation film by a source side injection method.

12. The non-volatile semiconductor memory device according to claim 11,
wherein a voltage value of a voltage applied to the first gate electrode in the program operation of the memory cell is equal to a voltage value of a voltage applied to the first gate electrode in the first operation configuring a part of the erase operation of the memory cell.

13. The non-volatile semiconductor memory device according to claim 12,
wherein the voltage is supplied to the first gate electrode in the first operation configuring the part of the erase operation of the memory cell using a power source circuit supplying a voltage to the first gate electrode in the program operation of the memory cell.

14. The non-volatile semiconductor memory device according to claim 1,
wherein the silicon oxide film has a film thickness of 3 nm or larger.

15. The non-volatile semiconductor memory device according to claim 1,
wherein the charge accumulation film is composed of a silicon nitride film and a silicon oxynitride film formed over the silicon nitride film.

16. The non-volatile semiconductor memory device according to claim 1,
wherein the charge accumulation film is a multilayered film of a first silicon oxynitride film, a silicon nitride film formed over the first silicon oxynitride film and a second silicon oxynitride film formed over the silicon nitride film.

17. The non-volatile semiconductor memory device according to claim 3,
wherein the first gate electrode is composed of a p-type polysilicon film.

18. A non-volatile semiconductor memory device comprising:
a memory cell comprising:
(a) a first semiconductor region and a second semiconductor region formed in a semiconductor substrate so as to be separated from each other;
(b) a first dielectric film formed over an upper portion of the semiconductor substrate over a portion between the first semiconductor region and the second semiconductor region; and
(c) a first gate electrode formed over the first dielectric film,
wherein the first dielectric film comprises:
(b1) a silicon oxide film; and
(b2) a charge accumulation film formed over the silicon oxide film and having a function of accumulating a charge,
wherein first operation of making a threshold voltage of the memory cell lower than a threshold voltage of the memory cell in a program state is performed by applying a positive voltage larger than a voltage applied to the semiconductor substrate to the first gate electrode, and then second operation of making the threshold voltage of the memory cell still lower is performed by injecting holes generated using a band-to-band tunneling phenomenon in the semiconductor substrate into the charge accumulation film so as to complete erase operation.

19. The non-volatile semiconductor memory device according to claim 18,
wherein a second silicon oxide film is formed between the charge accumulation film and the first gate electrode.

20. The non-volatile semiconductor memory device according to claim 19,
wherein the second silicon oxide film has a film thickness of 3 nm or smaller.
